(19) United States
(12) Patent Application Publication
(10) Pub. No.: US 2024/0119337 A1
(43) Pub. Date: Apr. 11, 2024

(54) ENGINEERING FAST BIAS-PRESERVING GATES ON STABILIZED CAT QUBITS

(71) Applicant: The University of Chicago, Chicago, IL (US)

(72) Inventors: Qian XU, Chicago, IL (US); LIANG JIANG, Chicago, IL (US)

(73) Assignee: The University of Chicago, Chicago, IL (US)

(21) Appl. No.: 18/272,410

(22) PCT Filed: Jan. 14, 2022
(86) PCT No.: PCT/US2022/012490

§ 371 Date: Jul. 14, 2023

Related U.S. Application Data
(60) Provisional application No. 63/138,185, filed on Jan. 15, 2021.

(51) Int. Cl. G06N 10/70; G06N 10/20; G06N 10/40; H03K 17/92

(52) U.S. Cl. CPC G06N 10/70; G06N 10/20; G06N 10/40; H03K 17/92

(57) ABSTRACT

The present disclosure describes various methods, systems, and storage medium for engineering fast bias-preserving gates on stabilized cat qubits. One method for performing a quantum operation on a qubit using a noise-bias-preserving (NBP) quantum gate includes obtaining and stabilizing the qubit; determining a type of the NBP quantum gate associated with the quantum operation, according to type of the NBP quantum gate, the quantum operation on the qubit to obtain a modified qubit, the quantum operation comprising a base gate drive and a counterdiabatic (CD) control drive. Another method for stabilizing a qubit for quantum storage includes obtaining a qubit; in response to the qubit being in an idle state, applying a two-photon dissipation operation on the qubit to stabilize the qubit, the two-photon dissipation operation corresponding to a two-photon drive.

### RELATED APPLICATION

This application is based on and claims the benefit of priority to U.S. Provisional Application No. 63/138,185 filed on Jan. 15, 2021, which is herein incorporated by reference in its entirety.

### GOVERNMENT LICENSE RIGHTS

This invention was made with government support under grant numbers W911NF-18-1-0020, W911NF-18-1-0212, W911NF-16-1-0349, and FA9550-19-1-0399 awarded by Army Research Office and grant numbers 1640959, 1936118, and 1941583 awarded by National Science Foundation. The government has certain rights in the invention.

### FIELD OF THE INVENTION

This disclosure relates to a method and system for creating fast bias-preserving gates on stabilized cat qubits for quantum computing, quantum information processing, and quantum storage.

### BACKGROUND OF THE INVENTION

Qubits with biased noise channel can have important applications in fault-tolerant quantum error correction (QEC), as some QEC codes can be tailored toward the biased noise to exhibit higher error threshold and more favorable resource over-head. With realistic circuit-level noise it is essential for gate operations to preserve the noise bias in order to maintain the biased noise channel for effective fault-tolerant QEC.

In some implementations, multi-component cat qubits, e.g., two-component cat qibuits, may be stabilized to possess biased noise channels and may be operated with a set of noise bias-preserving (NBP) quantum gates. However, there may be some problems/issues associated with such cat qubit implementations for NBP operations. One problem/issue may be that such implementations, in order to preserve noise bias, may be limited to adiabatic quantum operations, which use relatively weak drives, leading to slow quantum gates. Conventional non-adiabatic NBP operations using stronger drives would provide higher gate speed but would also create relatively high non-recoverable quantum information leakage, thereby resulting in loss of noise bias and/or reduction of gate fidelity.

The present disclosure describes various embodiments for performing fast, bias-preserving, and high-fidelity gate operations while stabilizing some example cat qubits and preserving noise bias, thereby addressing at least some of the problems/issues described above by suppressing leakage, preserving noise bias, and reducing non-adiabatic error during the quantum gate operation.

### SUMMARY OF THE INVENTION

In view of this, embodiments of the present disclosure are expected to provide a method, apparatus, and a storage medium for performing fast bias-preserving gate operations and stabilizing cat qubits.

According to one aspect, an embodiment of the present disclosure provides a method for performing a quantum operation on a qubit using a noise-bias-preserving (NBP) quantum gate. The method includes obtaining and stabilizing the qubit; determining a type of the NBP quantum gate associated with the quantum operation; and applying, according to the type of the NBP quantum gate, the quantum operation on the qubit to obtain a modified qubit, the quantum operation comprising a base gate drive and a counterdiabatic (CD) control drive.

According to another aspect, an embodiment of the present disclosure provides a method for stabilizing a qubit for quantum storage. The method includes obtaining a qubit, the qubit being a multi-component cat qubit; in response to the qubit being in an idle state, applying a two-photon dissipation operation on the qubit to stabilize the qubit, the two-photon dissipation operation corresponding to a two-photon drive.

According to another aspect, an embodiment of the present disclosure provides an apparatus for performing quantum computing and/or quantum error correction. The includes comprising a first device storing a qubit (e.g., a multi-component cat qubit) and a second device performing a gate operation on the qubit, and the apparatus is configured to perform a portion or all of the above methods.

According to another aspect, an embodiment of the present disclosure provides an apparatus for storing quantum information. The apparatus includes a first device storing a qubit (e.g., a multi-component cat qubit) and a second device performing a two-photon dissipation operation on the qubit, and the apparatus is configured to perform a portion or all of the above methods.

According to another aspect, an embodiment of the present disclosure provides a computer program product comprising a computer-readable program medium code stored thereupon. The computer-readable program medium code, when executed by a processor, causing the processor to implement a portion or all of the above methods.

The above and other aspects and their implementations are described in greater detail in the drawings, the descriptions, and the claims.

### BRIEF DESCRIPTION OF THE DRAWINGS

For a more complete understanding of the invention, reference is made to the following description and accompanying drawings, in which:

FIG. 1A-FIG. 1B are flow diagrams of various embodiments disclosed in the present disclosure;

FIG. 2 is a schematic diagram of an embodiment of an apparatus disclosed in the present disclosure;

FIG. 3 illustrates a schematic diagram of a classical computer system;

FIG. 4 illustrates a schematic diagram of a quantum computer system;

FIG. 5 shows a schematic diagram of various embodiments in the present disclosure, illustrating a double-well potential representing the Kerr parametric oscillator (KPO): the eigenenergies of Ĥ_{KPO} are plotted as dashed black lines; the delocalized eigenstates of Ĥ_{KPO} and the local states in each well are visualized by plotting their wigner functions in phase space; as the energy increases and approaches the potential barrier, the tunneling between two wells increases and the two local states overlap more with each other;

FIG. 6 shows a schematic diagram of various embodiments in the present disclosure, illustrating mechanism of the non-adiabatic Z errors while implementing the Z rotation: |ψ₀^{±} [symbol] , |ψ₁^{±} [symbol] are the fist two pair of excited states of Ĥ_{KPO}; the solid arrows represent the coherent coupling between different states by â+â^{†}while the dashed arrows represent represent the incoherent decay of excited states in the presence of [symbol] [â²−α²];

FIG. 7A-FIG. 7F show charts of various embodiments in the present disclosure, illustrating the non-adiabatic Z and X errors of three type of gates with different control schemes as functions of K(κ₂)T; FIGS. 7A and 7B show Z rotation; FIGS. 7C and 7D show ZZ rotation; FIGS. 7C and 7D show CX gate; the dashed black curves are the errors of dissipative gates; the solid red, green and blue curves are the errors of gates on Kerr cat using Hard, Gaussian and CD control respectively;

FIG. 8A-FIG. 8D show charts of various embodiments in the present disclosure, illustrating performance of the CX gates using different control schemes in the presence of photon loss: FIGS. 8A and 8B show the total Z and X error rates as functions of K(κ₂)T at κ₁/K(κ₂)=10⁻⁴; the “BP” gate time T′_{Gauss}, T′_{CD} of the CX gate on Kerr cat with Gaussian and CD control are marked; FIG. 8C shows the minimum Z error rates P*_{z} and the “BP” Z error rates P′_{z} at “BP” gate time T′_{CD} using different control schemes as functions of κ₁/K(κ₂); FIG. 8D shows the gate time T* maximizing the gate fidelity and the “BP” gate time T′ using different control schemes as functions of κ₁/K(κ₂);

FIG. 9 shows a schematic diagram of various embodiments in the present disclosure, illustrating a quantum error correction (QEC) circuit of the repetition cat;

FIG. 10 shows charts of various embodiments in the present disclosure, illustrating minimal logical error rate of the repetition-cat qubit and the optimal choice of the repetition code distance using different type of physical controlled-not (CX) gates; and

FIG. 11 shows a schematic diagram of various embodiments in the present disclosure, illustrating Fourier spectrum of different pulses.

### DETAILED DESCRIPTION

The description and accompanying drawings above provide specific example embodiments and implementations. Drawings containing device structure and composition, for example, are not necessarily drawn to scale unless specifically indicated. Subject matter may, however, be embodied in a variety of different forms and, therefore, covered or claimed subject matter is intended to be construed as not being limited to any example embodiments set forth herein. A reasonably broad scope for claimed or covered subject matter is intended. Among other things, for example, subject matter may be embodied as methods, devices, components, or systems. Accordingly, embodiments may, for example, take the form of hardware, software, firmware or any combination thereof.

Throughout the specification and claims, terms may have nuanced meanings suggested or implied in context beyond an explicitly stated meaning. Likewise, the phrase “in one embodiment/implementation” as used herein does not necessarily refer to the same embodiment and the phrase “in another embodiment/implementation” as used herein does not necessarily refer to a different embodiment. It is intended, for example, that claimed subject matter includes combinations of example embodiments in whole or in part.

Unless defined otherwise, all technical and scientific terms used herein have the same meaning as commonly understood by one of skill in the art to which the invention pertains. Although any methods and materials similar to or equivalent to those described herein can be used in the practice or testing of the present invention, the preferred methods and materials are described herein.

In general, terminology may be understood at least in part from usage in context. For example, terms, such as “and”, “or”, or “and/or,” as used herein may include a variety of meanings that may depend at least in part on the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

The embodiments of the present disclosure provide a method, an apparatus, and a non-transitory computer readable storage medium for performing fast bias-preserving gate operations and stabilizing cat quantum bits (qubits).

Quantum computing and quantum information processing may potentially solve practical problems in a range of areas, which may not be realistically solvable by classical computing on classical computers alone. Quantum computing and quantum information process may need at least two building blocks: a device to initialize, maintain, stabilize, or establish at least one qubit; and a set of quantum gates to perform quantum operations on one or more qubits to obtain one or more modified qubits. However, qubits and/or quantum gates may be prone to unintended interference/decoherence from outer environment and/or imperfection in the device. For example, quantum gates are prone to errors, which may significantly lower the quality or fidelity of quantum gates.

Some quantum errors in general quantum information processing may be correctable using quantum error correction (QEC) techniques. In some implementations, QEC codes may be tailored towards biased quantum noise to exhibit higher error threshold. As such, noise bias may be critical for some QEC techniques. In some implementations, multi-component stabilized cat qubits may possess such noise bias channels and thus may be considered as a platform for implementation of these QEC codes. These multi-component cat qubit may be a Schrodinger Cat qubit (or simply cat qubit) including coherent quantum superposition of a plurality of quantum states in a quantum mechanical subspace. In some implementations, a two-component cat qubit may be stabilized in a Kerr nonlinear oscillator, which may be referred as Kerr cat qubit. In some other implementations, a two-component cat qubit may engineered via two-photon dissipation, which may be referred as dissipative cat qubit. Some or all of the above cat qubits may be stabilized and/or may possess a biased noise channel, and/or may undergo various quantum gate operations via a set of bias-preserving (BP) gates. In some implementations, some quantum gate operation on a cat qubit (for example, a Z rotation gate operation on a Kerr cat qubit) may induce relatively large leakage, which significantly affects the fidelity and/or preservation of noise bias of the quantum gate operation. Various embodiments in the present disclosure may provide an improved control for the quantum gate operation on a cat quibit so as to suppress the leakage, improving preservation of noise bias and/or fidelity of the quantum gate operation.

In some implementations, a speed of gate operation, a fidelity of the gate operation, and the preservation of noise bias for Kerr cat qubits and dissipative cat qubits may be conflicted, as higher gate speed generally involves greater non-adiabaticity and hence higher leakage out of the quantum subspace of the cat qubit. For example, a Z gate operation (see below) on dissipative cat qubits using hard non-adiabatic pulses (square non-adiabatic pulse) may result in significant loss of gate fidelity. For another example, a Z gate operating on Kerr cat qubit using hard pulse may result in non-adiabatic loss of noise bias even though gate fidelity may still be maintained to a better extent than the dissipative cat qubit due to the unitary nature of its operations. Therefore, some or all gate operations on either Kerr or dissipative cat qubit may have to be implemented adiabatically with a driving strength much smaller than the energy gap (or dissipation gap) to protect the cat qubit from loss of noise bias and noise bias. This limitation on driving strength associated with adiabatic gate operation may limit the speed of the gate operation and/or the fidelity of the gate operation.

In some implementations, compared to the dissipative cat qubit, the Kerr cat qubit may support faster gate operations with higher gate fidelity due to a unitary nature of the gates. However, these unitary gates may not be able to keep the high noise bias as good as the dissipative gates do under some circumstances. Various embodiments in the present disclosure may provide a shortcuts to adiabaticity (STA) to preserving the noise bias in noise-bias-preserving (NBP, or BP) gates under non-adiabatic drive on Kerr cat qubits to suppress their non-adiabatic errors so that they may have high gate fidelity and high noise bias simultaneously in the presence of a realistic level of loss and/or leakage.

Various embodiments in the present disclosure may include improved gates, when applied to concatenated quantum error correction, may lead to lower logical error rate with lower resource overhead. In some implementations, an architecture that hybrids the Kerr nonlinearty with two-photon dissipation may be used to better protect the qubit. Optionally, in the architecture, the two-photon dissipation may be turned on when the cat qubit is idling to keep the system sufficiently cool, so as to stabilize the cat qubit; and/or the two-photon dissipation may be turned off when implementing gate operations (e.g., with the BP gates) to enable high-fidelity operations.

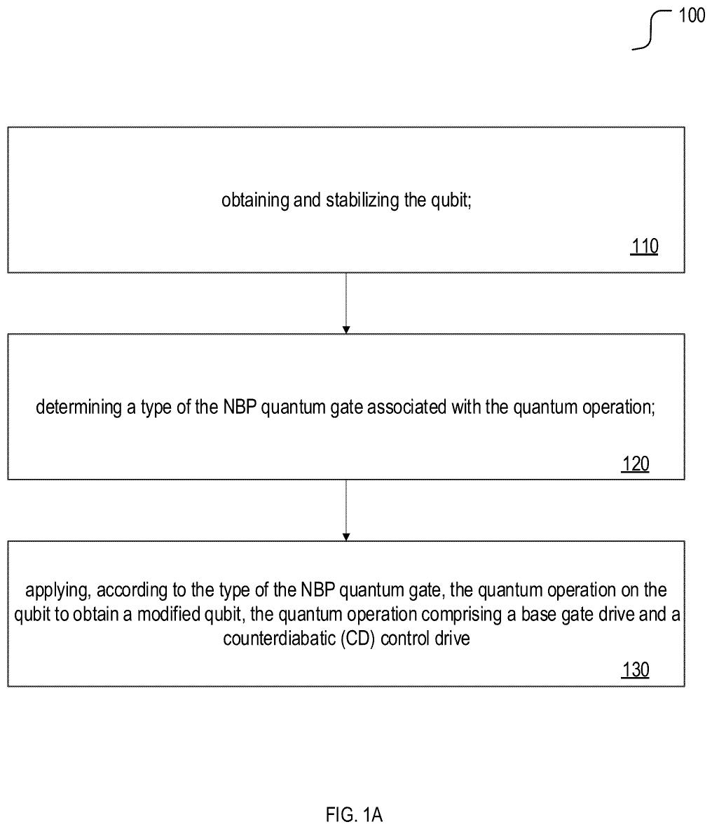

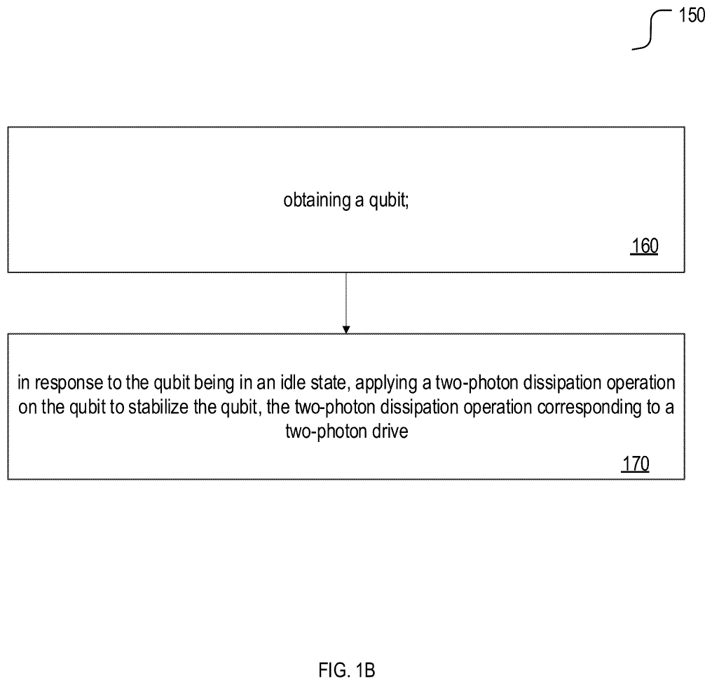

Referring to FIG. 1A, various embodiments in the present disclosure may include a method 100 for performing a quantum operation on a qubit using a noise-bias-preserving (NBP) quantum gate. The method 100 may include a portion or all of the following steps: step 110, obtaining and stabilizing the qubit; step 120, determining a type of the NBP quantum gate associated with the quantum operation; and step 130, applying, according to type of the NBP quantum gate, the quantum operation on the qubit to obtain a modified qubit, the quantum operation comprising a base gate drive and a counterdiabatic (CD) control drive.

The method 100 may be performed by any suitable quantum computing quantum information processing architecture with a quantum information processor, and may not depend on the underlying architecture of the quantum information processor. The quantum information processor may be any suitable quantum computing architecture that may perform universal quantum computation or quantum information processing, for example, a set of quantum gate operations. In some implementations, examples of quantum computing architecture may include super-conducting qubits, ion traps and optical quantum computer. A classical analog of quantum processor is a central processing unit (CPU) in a classical computer.

Referring to FIG. 1B, various embodiments in the present disclosure may include a method 150 for stabilizing a qubit for quantum storage. The method 150 may include a portion or all of the following steps: step 160, obtaining a qubit; and/or step 170, in response to the qubit being in an idle state, applying a two-photon dissipation operation on the qubit to stabilize the qubit, the two-photon dissipation operation corresponding to a two-photon drive.

The method 150 may be performed by any suitable quantum memory devices for storing one or more qubit, and may not depend on the underlying physical architecture of the quantum memory device.

In various embodiments in the present disclosure, a system may include a quantum computing portion and a classical computing portion in communication with the quantum computing portion. The quantum computing portion may perform a portion or all of the method 100 and/or the method 150; and/or the classical computing portion may perform other computation and/or provide interface between a user and the quantum computing portion.

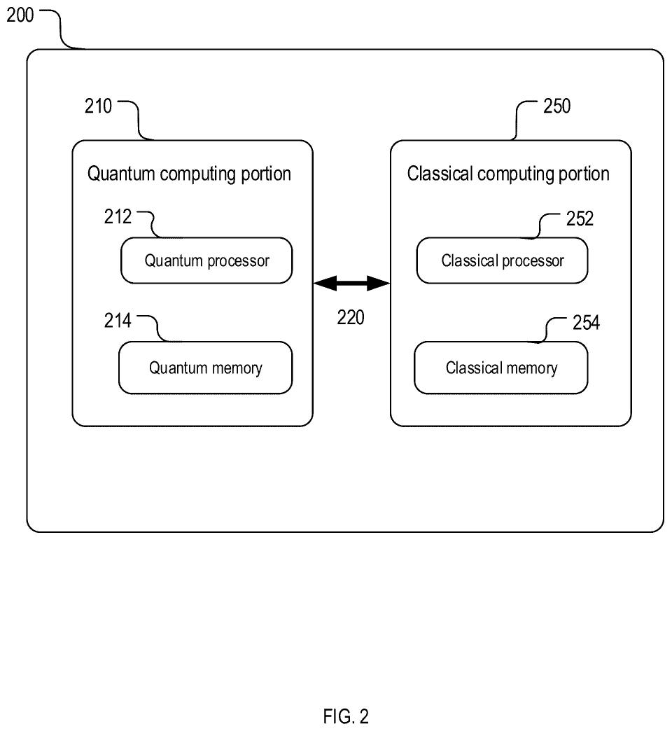

FIG. 2 shows an embodiment of a system 200 including a quantum computing portion 210 and a classical computing portion 250. The quantum computing portion 210 may include a quantum information processor 212 and the classical computing portion 250 may include a classical processor 252. Optionally, the quantum computing portion 210 may include a quantum memory 214. The quantum processor 212 and/or the quantum memory 214 may be realized by a same type or different types of quantum platforms, for example but not limited to superconducting circuits, trap ions, optical lattices, quantum dots, and linear optics in, for example, a driven Kerr nonlinear oscillator. In one implementation, the classical computing portion 250 may include a classical memory 254. The system 200 may also include an input (not shown in FIG. 2) and an output (not shown in FIG. 2). The input may receive data and/or instructions into the system; and/or after quantum computing, the output may output result from the system 200. The quantum computing portion 210 may communicate with the classical computing portion 250 via an interface 220.

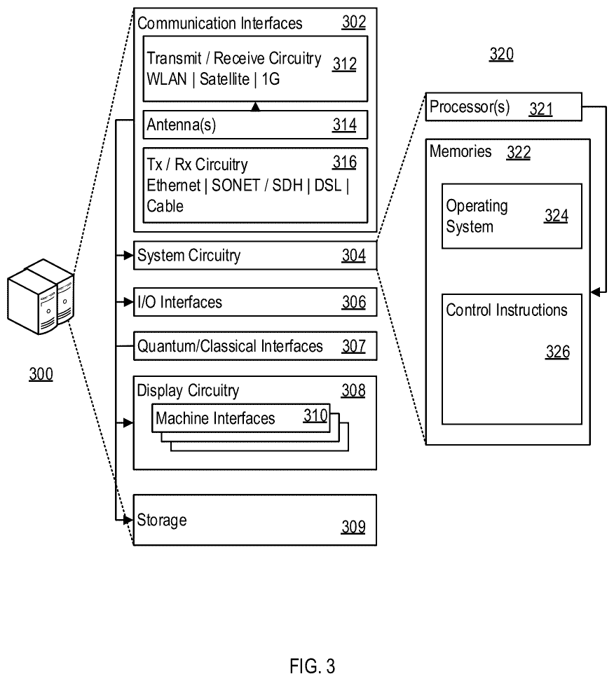

Referring to FIG. 3, in one implementation, a classical computer portion may be a portion of a classical computer system 300. The classical computer system 300 may include communication interfaces 302, system circuitry 304, input/output (I/O) interfaces 306, a quantum-classical interface 307, storage 309, and display circuitry 308 that generates machine interfaces 310 locally or for remote display, e.g., in a web browser running on a local or remote machine. The machine interfaces 310 and the I/O interfaces 306 may include GUIs, touch sensitive displays, voice or facial recognition inputs, buttons, switches, speakers and other user interface elements.

The machine interfaces 310 and the I/O interfaces 306 may further include communication interfaces with sensors and detectors. The communication between the computer system 300 and the sensors and detector may include wired commumication or wireless communication. The communication may include but not limited to, a serial communication, a parallel communication; an Ethernet communication, a USB communication, and a general purpose interface bus (GPIB) communication. Additional examples of the I/O interfaces 306 include microphones, video and still image cameras, headset and microphone input/output jacks, Universal Serial Bus (USB) connectors, memory card slots, and other types of inputs. The I/O interfaces 306 may further include magnetic or optical media interfaces (e.g., a CDROM or DVD drive), serial and parallel bus interfaces, and keyboard and mouse interfaces. The quantum-classical interface may include a interface communicating with a quantum computer.

The communication interfaces 302 may include wireless transmitters and receivers (“transceivers”) 312 and any antennas 314 used by the transmitting and receiving circuitry of the transceivers 312. The transceivers 312 and antennas 314 may support Wi-Fi network communications, for instance, under any version of IEEE 802.11, e.g., 802.11n or 802.11ac. The communication interfaces 302 may also include wireline transceivers 316. The wireline transceivers 316 may provide physical layer interfaces for any of a wide range of communication protocols, such as any type of Ethernet, data over cable service interface specification (DOCSIS), digital subscriber line (DSL), Synchronous Optical Network (SONET), or other protocol. In another implementation, the communication interfaces 302 may further include communication interfaces with the sensors and detectors.

The storage 309 may be used to store various initial, intermediate, or final data. In one implementation, the storage 309 of the computer system 300 may be integral with a database server. The storage 309 may be centralized or distributed, and may be local or remote to the computer system 300. For example, the storage 309 may be hosted remotely by a cloud computing service provider.

The system circuitry 304 may include hardware, software, firmware, or other circuitry in any combination. The system circuitry 304 may be implemented, for example, with one or more systems on a chip (SoC), application specific integrated circuits (ASIC), microprocessors, discrete analog and digital circuits, and other circuitry. For example, the system circuitry 304 may include one or more instruction processors 321 and memories 322. The memories 322 stores, for example, control instructions 326 and an operating system 324. In one implementation, the instruction processors 321 execute the control instructions 326 and the operating system 324 to carry out any desired functionality related to the controller.

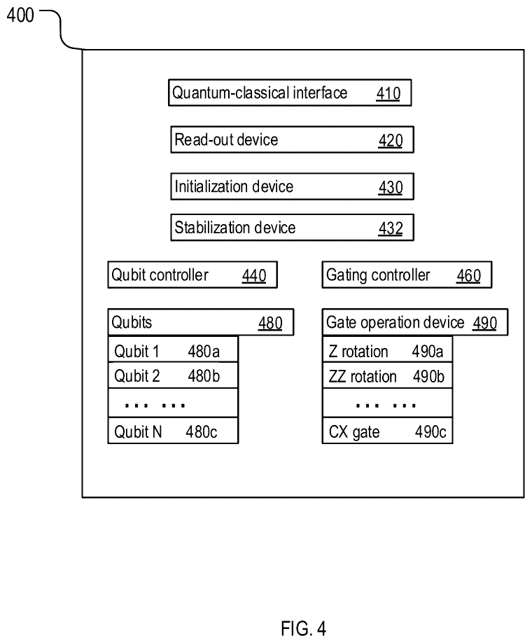

Referring to FIG. 4, in one implementation, a quantum computer portion 210 of FIG. 2 may be an entirety or part of a quantum computer system 400 and may further include components not depicted in FIG. 4. The quantum computer system 400 may include a portion or all of the following: a quantum-classical interface 410, a read-out device 420, an initialization device 430, a stabilization device 432, a qubit controller 440, and a gating controller 460. The quantum-classical interface 410 may provide an interface for communicating with a classical computer. The initialization device 430 may initialize the quantum computer system 400. The quantum computer system 400 may include a form of a quantum processor which includes one or more qubits. For example, the quantum computer system may include a plurality of qubits (qubit 1 480a, qubit 2 480b, . . . , and qubit N 480c, wherein N is a positive integer). The quantum computer system 400 may include a quantum gate operation device, which may perform at least one quantum gate operation, which may include, for example, one or more of of Z rotation gate 490a, ZZ rotation gate 490b, . . . , and controlled-not (CX) gate 490c.

Referring to FIG. 1A, step 110 may include obtaining and stabilizing the qubit. In some implementations, the qubit may be a Schrodinger Cat qubit (cat, or cat qubit) comprising coherent quantum superposition of a plurality of quantum states. In the present disclosure, various embodiments are described with some particular types of cat qubits as examples, which do not constitute a limitation to the present disclosure; and various embodiments and underlying principles in the present disclosure may be generally applicable to any types of cat qubits or any types of qubits.

In some other implementations, Kerr nonlinear cat qubits may be used and stabilized. Correspondingly, step 110 may include stabilizing the qubit in a Kerr nonlinear oscillator with a parametric two-photon drive. The Kerr nonlinear oscillator with the parametric two-photon drive may be used to stabilize the qubit between and/or during gate operations. The Kerr nonlinear oscillator with the parametric two-photon drive is associated with a stabilization Hamiltonian satisfying Ĥ_{KPO}=−K(â^{2†}−α²)(â²−α²), wherein: Ĥ_{KPO} is the Hamiltonian for the Kerr oscillator, K indicates a strength of Kerr nonlinearity, α indicates a value in phase space, and â indicates an operator. Such stabilizing drive may be implemented alone, for example, to stabilize the qubit during an idle state, or along with other quantum gate operation drives during quantum gate operations.

In some other implementations, the method 100 may further include in response to the qubit being in an idle state, applying a two-photon dissipation operation on the qubit to stabilize the qubit to take advantage of the noise-bias-preserving capability associated with stabilization using the two-photon dissipation operation. Specifically, when the qubit is not underwent a gate operation, the qubit is in the idle state. During the idle state, the stability of the qubit may be maintained by engineered two-photon dissipation along with two-photon drive. When the qubit is used as a medium for storing quantum information between quantum gate oprations, the two-photon dissipation for stabilizing the qubit may be used to further cool the Kerr oscillator so that the qubit is coupled to a thermal bath with wide-band spectral density.

Referring to FIG. 1A, step 120 may include determining a type of the NBP quantum gate associated with the the quantum operation. In quantum computing, a quantum gate, also referred to as a quantum logic gate, may be a basic quantum circuit operating on one or more qubit. The quantum gate may have a plurality of types, which form a set of quantum gates for implement universal quantum computing and quantum information processing. The set of quantum gates may be building blocks of quantum circuits for building a quantum computing architecture, like classical logic gates are for conventional classical digital circuits. In some implementations, the type of the NBP quantum gate include but are not limited to one of a Z rotation gate, a ZZ rotation gate, or a controlled-NOT (CX) gate.

In some implementations, the quantum operation drive may include at least two parts. A first part may be referred as a base gate drive, and a second part may be referred as a counterdiabatic (CD) control drive. The base gate drive may include a Kerr nonlinear oscillator with parametric two-photon drive to stabilize the Kerr cat qubit, and may further include a gate operation drive specifically designed according to the type of the NBP quantum gate. In some implementations, the two components of the base gate drive may be separable. In some other implementations, the two components of the base gate drive may be non-separably and integrally designed for a particular type of the NBP quantum gate. The second component of the base drive, namely, the gate operation drive, may, for example, include one or more truncated Gaussian drive pulses, or other drive pulses derived from the truncated Gaussian drive pulses, as described in further detail below. In comparison to some hard driving pulses (e.g., square pulse), truncated Gaussian pulses may provide better frequency selectivity and smoothness, and in combination with the CD control drive pulses further described below, may provide better gate fidelity of noise bias preservation simultaneously in the presence of non-adiabaticity during gate operation.

In some implementations, the CD control drive may be designed according to the type of the NBP quantum gate, so as to avoid some of the issues/problems associated with non-adiabatic process. The CD control drive may correspond to a set of CD control pulses designed according to the type of the NBP quantum gate to counter the adverse effect as a result of a non-adiabatic base gate drive for achieving higher gate operation speed. The set of CD control drive pulses may constitute a time sequence of drives. Particularly for non-adiabatic gate operation on a cat qubit stabilized in a Kerr nonlinear oscillator under a parametric two-photon drive, the CD control pulses may be designed to counter the adverse effect of non-adiabatic leakage on the preservation of noise-bias during the quantum gate operation. The set of CD control pulses, for example, may be implemented as a function of a set of truncated Gaussian pulses from a family of truncated Gaussian pulses. The CD control drive may help with suppressing drive leakage, reducing non-adiabatic errors, improving speed of gate operations, countering loss of noise bias, and/or increasing fidelity of gate operations.

In some implementations when the operation type is the Z rotation gate, the quantum operation comprises a Z rotation control Hamiltonian satisfying:

Ĥ_{Z}(t)=Ĥ_{Z}⁽⁰⁾(t)+Ĥ_{cd}(t)

Ĥ_{Z}⁽⁰⁾(t)=−K(â^{2†}−α²)(â²−α²)+Ω₀(t)(â+â^{†})

Ĥ_{cd}(t)=uₓ(t)(a+a^{†})+iu_{y}(t)(a−a^{†}) (1)

wherein: Ĥ_{Z}(t) indicates the Z rotation control Hamiltonian, Ĥ_{Z}⁽⁰⁾(t) indicates the base gate drive for the Z rotation gate, Ĥ_{cd}(t) indicates the CD control drive for the Z rotation gate, the K term indicates a stabilization drive with Kerr nonlinearity and with a parametric two-photon drive, Ω₀(t) indicates a base driving pulse, and uₓ(t) and u_{y}(t) indicate two CD control pulses. In some implementations, as described in more details in the following sections, the base driving pulse, Ω₀(t), may be one of a family of truncated Gaussian pulses; and/or each of the CD control pulses, uₓ(t) and u_{y}(t), may be a function of one or more of the family of truncated Gaussian pulses.

In some implementations, when the operation type is the ZZ rotation gate, the quantum operation may include a ZZ rotation control Hamiltonian satisfying:

Ĥ_{ZZ}(t)=Ĥ_{ZZ}⁽⁰⁾(t)+Ĥ_{cd}(t)

Ĥ_{ZZ}⁽⁰⁾(t)=−K(â_{c}^{2†}−α²)(â_{c}²−α²)−K(âₜ^{2†}−α²)(âₜ²−α²)+Ω₀(t)(â_{c}âₜ+â_{c}^{†}âₜ^{†})

Ĥ_{cd}(t)=uₓ(t)(â_{c}âₜ+â_{c}^{†}âₜ^{†})+iu_{y}(t)(â_{c}âₜ−â_{c}^{†}âₜ^{†}) (2)

wherein: Ĥ_{ZZ}(t) indicates the ZZ rotation control Hamiltonian, Ĥ_{ZZ}⁽⁰⁾(t) indicates the base gate drive for the ZZ rotation gate, Ĥ_{cd}(t) indicates the CD control drive for the ZZ rotation gate, the K term indicates a stabilization drive with Kerr nonlinearity and with a parametric two-photon drive, Ω₀(t) indicates a base driving pulse, and uₓ(t) and u_{y}(t) indicate two CD control pulses. In some implementations, as described in more details in the following sections, the base driving pulse, Ω₀(t), may be one of a family of truncated Gaussian pulses; and/or each of the CD control pulses, uₓ(t) and u_{y}(t), may be a function of one or more of the family of truncated Gaussian pulses.

In some implementations, when the operation type is the CX gate, the quantum operation comprises a CX gate control Hamiltonian satisfying:

$${\hat{H}}_{CX} ( t ) = {\hat{H}}_{CX}^{( 0 )} ( t ) + {\hat{H}}_{c d} ( t ) \qquad ( 3 )$$

$${\hat{H}}_{CX}^{( 0 )} ( t ) = - K ( {\hat{a}}_{c}^{†2} - {α}^{2} ) ( {\hat{a}}_{c}^{2} - {α}^{2} ) K [ {\hat{a}}_{t}^{†2} - {α}^{2} {e}^{- 2 i ϕ ( t )} ( \frac{α - {\hat{a}}_{c}^{†}}{2 α} ) - {α}^{2} ( \frac{α - {\hat{a}}_{c}^{†}}{2 α} ) ] \times [ {\hat{a}}_{t}^{2} - {α}^{2} {e}^{2 i ϕ ( t )} ( \frac{α - {\hat{a}}_{c}}{2 α} ) - {α}^{2} ( \frac{α + {\hat{a}}_{c}}{2 α} ) ] - \frac{1}{2} ϕ ( t ) \frac{( 2 α - {\hat{a}}_{c}^{†} - {\hat{a}}_{c} )}{2 α} ⊗ ( {\hat{a}}_{t}^{†} {\hat{a}}_{t} - {α}^{2} )$$

$${\hat{H}}_{c d} ( t ) = i {u}_{0} ( t ) \frac{{\hat{a}}_{c} + {\hat{a}}_{c}^{†}}{4 α} ⊗ ( {\hat{a}}_{t}^{†} {\hat{a}}_{t} - {α}^{2} ) + {u}_{1} ( t ) ( {\hat{a}}_{c} + {\hat{a}}_{c}^{†} ) + i {u}_{2} ( {\hat{a}}_{c}^{2} + {\hat{a}}_{c}^{2 †} ) + {u}_{3} ( t ) [ ( {e}^{2 i ϕ ( t )} - 1 ) {\hat{a}}_{t}^{2 †} + ( {e}^{- 2 i ϕ ( t )} - 1 ) {\hat{a}}_{t}^{2 †} ]$$

wherein: Ĥ_{CX}(t) indicates the CX gate control Hamiltonian, Ĥ_{CX}⁽⁰⁾(t) indicates the base gate drive for the CX gate, Ĥ_{cd}(t) indicates the CD control drive for the CX gate, \dot{ϕ}(t) indicates a base driving pulse, and u₀(t), u₁(t), u₂(t), and u₃(t) indicate four CD control pulses. In some implementations, as described in more details in the following sections, the base driving pulse, Ω₀(t), may be one of a family of truncated Gaussian pulses; and/or each of the CD control pulses, u₀(t), u₁(t), u₂(t), and u₃(t), may be a function of one or more of the family of truncated Gaussian pulses.

In some implementations, quantum error correction (QEC) may be used in quantum computing and/or quantum information processing to protect quantum information from errors due to decoherence and other quantum noise due to environments and/or imperfections. A QEC quantum circuit may perform measurements on a plurality of qubit with a series of quantum operations. These measurements may not disturb the quantum information in the encoded state, and may provide information about the errors due to quantum noise. Based on the information provided from these measurements, a qubit may be corrected, via QEC with a decoder, to obtain a QEC-corrected qubit.

In some implementations, a QEC may be performed on the modified qubit to obtain a QEC-corrected qubit. For example in the following sections, a QEC circuit of a repetition cat qubit is described in more details, considering various quantum error/noises, for example, state-preparation error/noise, idling error/noise, gate operation error/noise, and/or measurement error/noise. In some other implementations, the QEC circuit may comprise a concatenated QEC; and/or the modified qubit may be corrected with a minimum weight prefect matching (MWPM) decoder to obtain the QEC-corrected qubit.

Referring back to FIG. 1B, the method 150 may further include performing a quantum operation on the qubit; and/or during the quantum operation, stabilizing the qubit using a Kerr oscillator with a parametric two-photon drive. The Kerr oscillator having a Hamiltonian satisfying Ĥ_{KPO}=−K(â^{2†}−α²)(â²−α²), wherein: wherein: Ĥ_{KPO} is the Hamiltonian for the Kerr oscillator, K indicates a strength of Kerr nonlinearity, α indicates a value in phase space, and â indicates an operator.

The present disclosure also describes various embodiment of an apparatus for performing quantum computing. The apparatus includes a first device storing a qubit and a second device performing a gate operation on the qubit. The apparatus is configured to perform any portion or all of the methods, embodiments, and/or implementations described in the present disclosure.

The present disclosure also describes various embodiment of an apparatus for storing quantum information. The apparatus includes a first device storing a qubit and a second device performing a two-photon dissipation operation on the qubit to stabilize the qubit. The apparatus is configured to perform any portion or all of the methods, embodiments, and/or implementations described in the present disclosure.

The present disclosure also describes various embodiment of a computer program product comprising a computer-readable program medium code stored thereupon. The computer-readable program medium code, when executed by a processor, causing the processor to implement any portion or all of the methods, embodiments, and/or implementations described in the present disclosure.

The present disclosure describes various embodiments in more details below.

### Introduction

A two-component cat qubit can be stabilized in a driven Kerr nonlinear oscillator, referred as Kerr cat, or by engineered driven two-photon dissipation, which may be called as dissipative cat. Such stabilized cat qubits possess a biased noise channel and a set of bias-preserving (BP) gates have been separately proposed on these two type of cats. Although both limited by the non-adiabatic effects, compared to the dissipative cat, the Kerr cat supports faster gate operations with higher gate fidelity due to the unitary nature of the gates. However, these unitary gates may not be able to keep the high noise bias as good as the dissipative gates do, as is the case when they are controlled by the originally proposed simple scheme. In the present disclosure, shortcuts to adiabaticity (STA) methods are applied to the BP gates on Kerr cat to suppress their non-adiabatic errors so that they can have high gate fidelity and high noise bias simultaneously in the presence of a realistic level of photon loss. The improved gates, when applied to concatenated quantum error correction, can lead to lower logical error rate with lower resource overhead. Some embodiments use an architecture that hybrids the Kerr nonlinearty with two-photon dissipation to better protect the qubit. In this architecture, the two-photon dissipation should be turned on when the cat is idling to keep the system sufficiently cool while turned off when implementing the the BP gates to enable high-fidelity operations.

Qubits with biased noise channel can have important applications in fault-tolerant quantum error correction (QEC), as some QEC codes can be tailored toward the biased noise to exhibit higher error threshold and more favorable resource over-head. With realistic circuit-level noise it is essential for gate operations to preserve the noise bias in order to maintain the biased noise channel. Such non-trivial biased-preserving gates have recently proposed on stabilized cat qubits.

A two-component cat qubit can be stabilized in a Kerr oscillator with parametric two photon drive. The Hamiltonian of such Kerr parametric oscillator (KPO) in the frame rotating at the oscillator frequency is:

$$\begin{matrix}{\hat{H}}_{KPO} = - K \hat{} {a}^{2 †} {\hat{a}}^{2} + P ( {\hat{a}}^{2} + {\hat{a}}^{2 †} ) \\ = - K ( {\hat{a}}^{2 †} - {α}^{2} ) ( {\hat{a}}^{2} - {α}^{2} )\end{matrix} \qquad ( 4 )$$

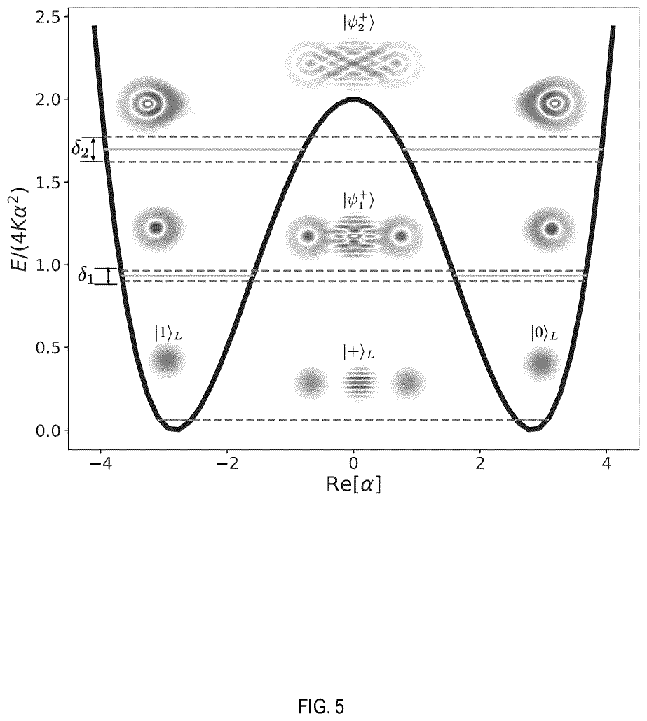

Such a Hamiltonian can be intuively viewed as a quasi-1d double-well potential with two minima α and −α in phase space, as schematically shown in FIG. 5. This potential supports pairs of nearly degenerate eigenstates |ψₙ^{±} [symbol] with eigenenergies Δₙ±δₙ/2, where ± labels the even and odd photon number parity respectively and δₙ denotes the energy splitting between the n-th pair of excited, which is exponentially suppressed by α² provided that Δₙ is well below the potential barrier. The exactly degenerate ground subspace is spanned by the Schrodinger Cat states |ψ₀^{±} [symbol] = [symbol] _{±}(|α [symbol] ±|−α [symbol] ), which is gapped from all other excited states by energy Δ₁≈4K|α|². The cat subspace is stabilized by this large energy gap if there is no resonant excitation.

It has been proposed recently that such a cat qubit can also be stabilized by engineered two-photon dissipation along with two-photon drive:

$$\frac{d ρ}{dt} = [ {ϵ}_{2} {\hat{a}}^{2 †} - {ϵ}_{2}^{*} {\hat{a}}^{2} , ρ ] + {κ}_{2} 𝒟 [ {\hat{a}}^{2} ] ρ = {κ}_{2} 𝒟 [ {\hat{a}}^{2} - {α}^{2} ] ρ \qquad ( 5 )$$

where

$$𝒟 [ \hat{A} ] \hat{ρ} = \hat{A} \hat{ρ} {\hat{A}}^{†} - \frac{1}{2} \{ {\hat{A}}^{†} \hat{A} , \hat{ρ} \} .$$

The protection from this Lindbladian can be understood similarly except that now the cat logical space is the attractive decoherece-free subspace (DFS) protected by the dissipation gap Δ^{d}=Δ₁ and all eigenstates decay exponentially into the logical space.

One can in principle hybrid these two type of stabilization to protect the cat qubit, i.e. applying two-photon dissipation to a strong Kerr nonlinear oscillator. And in fact, in the memory level, additional two-photon dissipation can be helpful to further cool the Kerr oscillator if, for example, the cat is coupled to a thermal bath with wide-band spectral density.

The computational basis of cat qubit may be defined as

$${{\vert 0 〉}_{L} ≡ \frac{\vert {ψ}_{0}^{+} 〉 + \vert {ψ}_{0}^{-} 〉}{\sqrt{2}} \approx \vert α 〉 , \vert 1 〉}_{L} ≡ \frac{\vert {ψ}_{0}^{+} 〉 - \vert {ψ}_{0}^{-} 〉}{\sqrt{2}} \approx \vert - α 〉 ,$$

where the approximation decreases exponentially with α². With this definition, the noise channel of such stabilized cat is strongly biased toward phase flip error \hat{Z} and in fact, the noise bias η≡P_{z}/Pₓ increases exponentially with |α|² provided that the leakage outside the cat logical space is sufficiently small. Here in the present disclosure, Pₓ may be used to denote all the non-Z type of errors for simplicity.

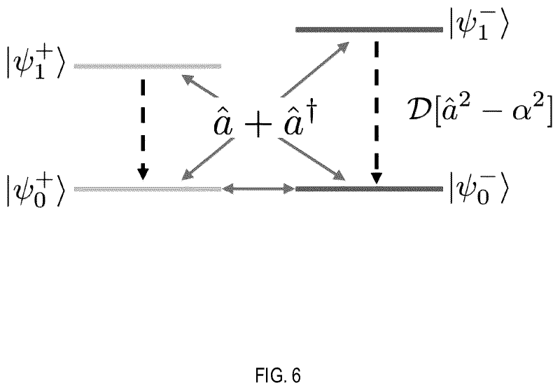

A set of bias-preserving gates have been proposed separately on kerr cat and Disspative cat, among which the Z-axis rotation (exp (iθ\hat{Z}/2)), ZZ rotation (exp (iθ\hat{Z}₁\hat{Z}₂/2)) and the CX gate have to be implemented adiabatically, i.e. |ϵ/Δ(Δ_{d})|<<1, where ϵ is the characteristic driving strength while Δ(Δ_{d}) is the energy gap (dissipation gap) protecting the cat. In the presence of photon loss, such limited gate speed translates to limited gate fidelity. Although both limited by the non-adiabtic effects, the BP gates on Kerr cat can be implemented faster than those on dissipative cat. To see this, the Z rotation may be first considered, which is implemented by applying a linear drive Ĥ_{Z}=Ω(t)â+Ω*(t)â^{†} on the stabilized cats. As shown in FIG. 6, while coupling |ψ₀⁺ [symbol] with |ψ₀⁻ [symbol] in the logical space the linear drive also couples the ground states to the excited states and induces leakage. For dissipative cat, the excited states are disspative so whenever the drive excite the qubit it decays immediately back into the logical space (assuming weak drive) with flipped parity. Such events are incoherent and can be effectively described by phase flip jumps in the logical space, or effetively, photon loss κ_{eff}(t) [symbol] [â]. The effective photon loss rate can be derived using the effective operator formalism as

$${κ}_{eff} ( t ) = \frac{{\vert Ω ( t ) \vert}^{2}}{{κ}_{2} {α}^{4}} .$$

Thus the total phase flip probability due to this adiabaticity after the gate time T is P_{z}^{NA}=∫ₜ₌₀^{T}κ_{eff}(t)dt. As information is continuously leaked to the environment it is hard to suppress the error accumulation with only unitary operations. This Z rotation on Kerr-cat, on the other hand, is unitary and the only error during the gate is off-resonant leakage. Although the leakage to the first pair of excited states, when being cooled back into the ground subspace after the gate, still becomes phase flip errors due to flipped parity, this leaked population can be inverted back into the logical space at the end of the gate with feasible unitary controls so that the non-adiabatic errors can be highly suppressed.

The Z rotation on kerr cat was originally proposed with simple hard (square) driving pulses, i.e.

$$Ω ( t ) = \frac{θ}{T} ,$$

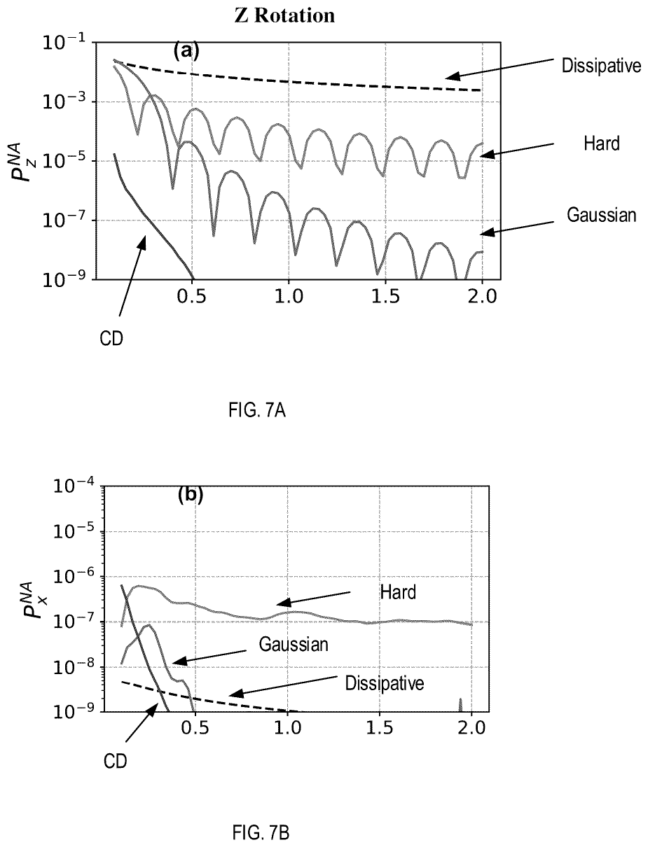

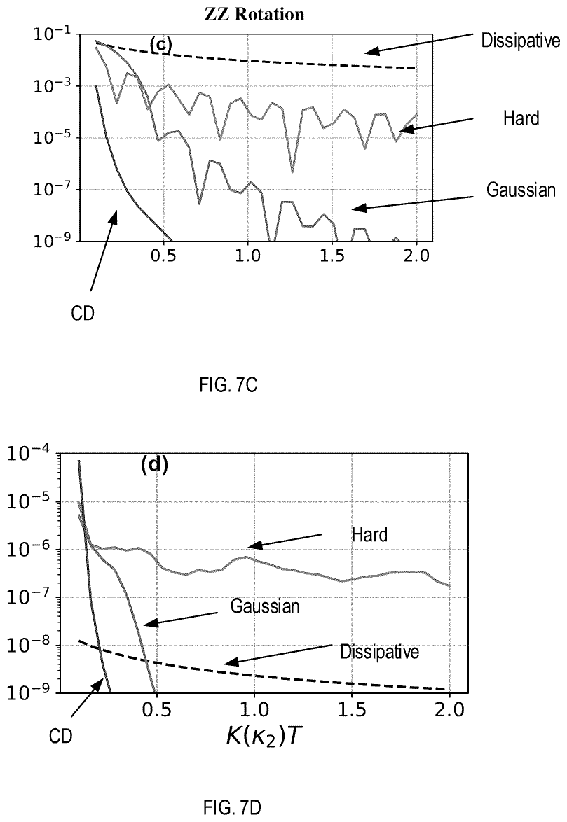

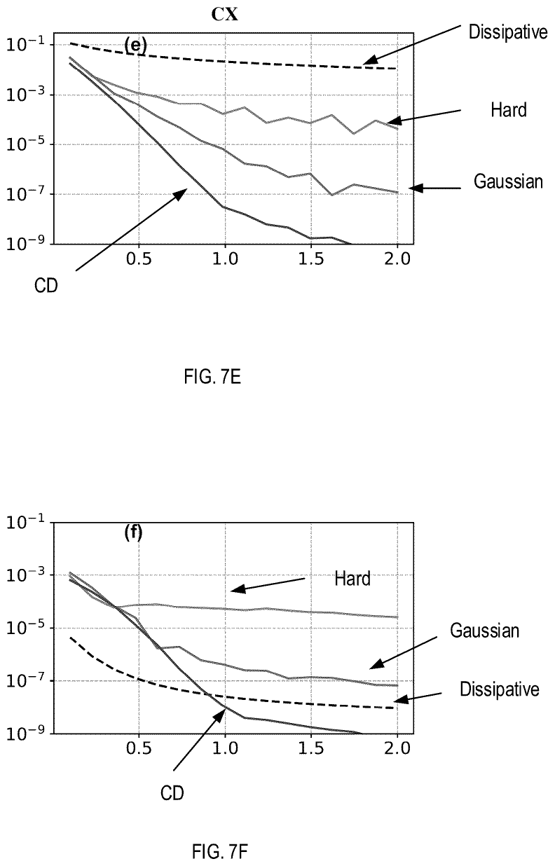

which can induce relatively large leakage. Even with this simple control the Z gate on Kerr cat already shows advantage over the disspative cat in terms of gate speed and gate fidelity (see FIGS. 7A-7F). However, the numerical results also show that non-adiabatic X error using this hard pulse can be much larger than the dissipative cat (see FIG. 7A) as the leakage to the higher excited states, e.g. the second pair of excitated states for α=\sqrt{8} shown in FIG. 5, can induce large tunneling between two wells. Similar gate behavior may be observed on ZZ rotation and CX gate. These numerical results manifest the need for finer control on the Kerr cat to further suppress the leakage, which is the major achievement of this work using the idea of shortcuts to adiabaticity.

### Counterdiabatic Control of Kerr Cat Qubits

To suppress the diabatic transitions, the base hard driving pulses may be first replaced with a family of truncated Gaussian pulses because of their better frequency selectivity and smoothness:

$${Ω}_{G , m} ( t ) = {A}_{m} {\{ exp [ - \frac{{( t - T / 2 )}^{2}}{2 {σ}^{2}} ] - exp [ - \frac{{( T / 2 )}^{2}}{2 {σ}^{2}} ] \}}^{m} \qquad ( 6 )$$

where m is chosen such that first m-1 derivatives of Ω_{G,m} start and end at 0, and Aₘ is a normalization constant determined by the amount of target rotation, σ is chose to be equal to T in various embodiments in the present disclosure. In various embodiments, shorthand “Gaussian” may be used to refer to this control scheme later. And then derivative-based transition suppression technique may be used to further suppress the leakage by adding some counterdiabatic (CD) drives to each gate, which will be referred to as “CD” control. For example, in various embodiments in the present disclosure, the size of the cat may be fixed as α²=8. The designed CD control Hamiltonians for Z rotation, ZZ rotation and CX gate are shown below.

### Z Rotation

Ĥ_{Z}(t)=Ĥ_{Z}⁽⁰⁾(t)+Ĥ_{cd}(t)

Ĥ_{Z}⁽⁰⁾(t)=−K(â^{2†}−α²)(â²−α²)+Ω₀(t)(â+â^{†})

Ĥ_{cd}(t)=uₓ(t)(a+a^{†})+iu_{y}(t)(a−a^{†}) (7)

with based driving pulse Ω₀=Ω_{G,2}(t) and CD pulses:

$${u}_{x} ( t ) = - \frac{{\ddot{Ω}}_{0} ( t )}{{Δ}_{1} {Δ}_{2}} + 0.84 \frac{{Ω}_{0}^{3} ( t )}{{Δ}_{2}^{2}} \qquad ( 8 )$$

$${u}_{y} ( t ) = - {\dot{Ω}}_{0} ( t ) + ( \frac{1}{{Δ}_{1}} + \frac{1}{{Δ}_{2}} )$$

### ZZ Rotation

Ĥ_{ZZ}(t)=Ĥ_{ZZ}⁽⁰⁾(t)+Ĥ_{cd}(t)

Ĥ_{ZZ}⁽⁰⁾(t)=−K(â_{c}^{2†}−α²)(â_{c}²−α²)−K(âₜ^{2†}−α²)(âₜ²−α²)+Ω₀(t)(â_{c}âₜ+â_{c}^{†}âₜ^{†})

Ĥ_{cd}(t)=uₓ(t)(â_{c}âₜ+â_{c}^{†}âₜ^{†})+iu_{y}(t)(â_{c}âₜ−â_{c}^{†}âₜ^{†}) (9)

with base driving pulse Ω₀=Ω_{G,3}(t) and CD pulses:

$${u}_{x} ( t ) = - {\ddot{Ω}}_{0} ( t ) [ \frac{1}{{Δ}_{a} {Δ}_{b}} + \frac{1}{{Δ}_{a} {Δ}_{c}} + \frac{1}{{Δ}_{b} {Δ}_{c}} ] + 0.126 \frac{{Ω}_{0}^{3} ( t )}{{Δ}_{1}^{2}} \qquad ( 10 )$$

$${u}_{y} ( t ) = - {Ω}_{0} ( t ) ( \frac{1}{{Δ}_{a}} + \frac{1}{{Δ}_{b}} + \frac{1}{{Δ}_{c}} ) + \frac{{{Ω}^{…}}_{0} ( t )}{{Δ}_{a} {Δ}_{b} {Δ}_{c}} where$$

$${Δ}_{a} = {Δ}_{1} , {Δ}_{b} = 2 {Δ}_{1} , {Δ}_{c} = {Δ}_{1} + {Δ}_{2}$$

### CX Gate

$${\hat{H}}_{CX} ( t ) = {\hat{H}}_{CX}^{( 0 )} ( t ) + {\hat{H}}_{c d} ( t ) \qquad ( 11 )$$

$${\hat{H}}_{CX}^{( 0 )} ( t ) = - K ( {\hat{a}}_{c}^{†2} - {α}^{2} ) ( {\hat{a}}_{c}^{2} - {α}^{2} ) K [ {\hat{a}}_{t}^{†2} - {α}^{2} {e}^{- 2 i ϕ ( t )} ( \frac{α - {\hat{a}}_{c}^{†}}{2 α} ) - {α}^{2} ( \frac{α - {\hat{a}}_{c}^{†}}{2 α} ) ] \times [ {\hat{a}}_{t}^{2} - {α}^{2} {e}^{2 i ϕ ( t )} ( \frac{α - {\hat{a}}_{c}}{2 α} ) - {α}^{2} ( \frac{α + {\hat{a}}_{c}}{2 α} ) ] - \frac{1}{2} \dot{ϕ} ( t ) \frac{( 2 α - {\hat{a}}_{c}^{†} - {\hat{a}}_{c} )}{2 α} ⊗ ( {\hat{a}}_{t}^{†} {\hat{a}}_{t} - {α}^{2} )$$

$${\hat{H}}_{c d} ( t ) = i {u}_{0} ( t ) \frac{{\hat{a}}_{c} + {\hat{a}}_{c}^{†}}{4 α} ⊗ ( {\hat{a}}_{t}^{†} {\hat{a}}_{t} - {α}^{2} ) + {u}_{1} ( t ) ( {\hat{a}}_{c} + {\hat{a}}_{c}^{†} ) + i {u}_{2} ( t ) ( {\hat{a}}_{c}^{2} + {\hat{a}}_{c}^{2 †} ) + {u}_{3} ( t ) [ ( {e}^{2 i ϕ ( t )} - 1 ) {\hat{a}}_{t}^{2 †} + ( {e}^{- 2 i ϕ ( t )} - 1 ) {\hat{a}}_{t}^{2} ]$$

with base driving pulse \dot{θ}(t)=Ω_{G,1}(t) and CD pulses:

$${u}_{0} ( t ) = \frac{d}{dt} [ \frac{\dot{θ} ( t )}{{Δ}_{11} ( t )} ] \qquad ( 12 )$$

$${u}_{1} ( t ) = 0.675 \frac{[ 1 - cos ϕ ( t ) ] \dot{θ} ( t )}{{Δ}_{11} ( t )}$$

$${u}_{2} ( t ) = - 0.12 \frac{[ 2 sin ϕ ( t ) ] \dot{θ} ( t )}{{Δ}_{11} ( t )}$$

$${u}_{3} ( t ) = 0.3 \frac{\dot{θ} ( t )}{{Δ}_{11} ( t )} where$$

$${Δ}_{11} ( t ) = 2 {Δ}_{1} + \frac{{α}^{2}}{4} ( 1 - cos ϕ ( t ) ) .$$

For comparison, the original gates are proposed with simple hard pulses, i.e. Ω₀/\dot{θ}(t) are hard pulses and Ĥ_{cd}=0. For Gaussian control, the base driving pulses may be replaced with Gaussian pulses without adding CD terms, i.e. Ω₀/\dot{θ}(t)=Ω_{G,m}(t), Ĥ_{cd}=0.

To evaluate the gate performance with the control scheme, the non-adiabatic Z and X errors of each gate may be first numerically obtained by initializing to certain initial states, simulating Eqs. 7, 50, and 11, applying a strong two-photon dissipation (Eq. 5) at the end of each gate and calculating the state fidelity with target states. |+ [symbol] _{L}/|++ [symbol] _{L} may be chosen as initial state to extract Z errors while |0 [symbol] _{L}/|00 [symbol] _{L} to extract X errors. The results, in comparison with those obtained using other control schemes, are shown in FIGS. 7A-7F. The scaling of the non-adiabatic Z errors with gate time is summarized in Tab. 1. For dissipative cat, simple hard pulse may be used as the base driving pulse (simply using other pulses will not help), the non-adiabtic Z errors, which are given by integrating the effective phase flip rate over gate time, scales linearly with 1/κ₂T. For Kerr cat without CD terms, the non-adiabtic Z errors are proportional to the fourier component of the base driving pulse at energy gap Δ: |∫₀^{T}Ω₀(t)e^{-iΔt}dt|². So for hard control, the Z error scales quadratically with 1/KT (neglecting the fast oscillating terms) and using Gaussian control, the scaling to exponential scaling in the short-time limit may be improved while power-law scaling in the long-time limit, see other sections in the present disclosure for more details. If counterdiabatic drives are further added in addition to the Gaussian pulse shaping, the diabatic transitions may be further reduced and the exponential error scaling to the regime where errors are sufficiently small may be extended.

For all three gates, using smooth Gaussian pulses along with carefully designed CD drives can significantly reduce the non-adiabatic Z and X errors simultaneously. So using the designed control can greatly speed up the gates, which in the presence of photon loss, as will be shown in the next session, translates to higher gate fidelity, while preserving the high noise bias.

TABLE 1
The scaling of non-adiabatic gate errors with gate time using different
control schemes.

| Control | | | | |
|---|---|---|---|---|
| Scheme | Dissipative | Hard | Gaussian | CD |
| P_{z}^{NA} | $∝ \frac{1}{{κ}_{2} T}$ | $∝ \frac{1}{{( KT )}^{2}}$ | Exponential - power law | Exponential |

### Gate Performance in the Presence of Noise

In the presence of photon loss, the total Z error rate of the gates, which determines the gate fidelity, is given by:

P_{z}=P_{z}^{NA}+βκ₁|α|²T (13)

where κ₁ denotes the photon loss rate, P_{z}^{NA} denotes the non-adiabatic Z error discussed in the previous section and β depends on the gate, for Z rotation, β=1, for ZZ rotation and CX gate, β=2. For certain κ₁/K(κ₂), the minimal Z error rate P*_{z} at T* may be obtained by optimizing the choice of gate time. Plugging in the scaling of P_{z}^{NA} with T in Tab. 1., the scaling of P*_{z} with κ₁/K(κ₂) may be obtained. For gates on dissipative cat,

$${P}_{z , dissi}^{*} ∝ {( \frac{{κ}_{1}}{{κ}_{2}} )}^{1 / 2} .$$

For gates on Kerr cat with hard pulses,

$${P}_{z , Hard}^{*} ∝ {( \frac{{κ}_{1}}{K} )}^{2 / 3} .$$

While using Gaussian pulses or Gaussian pulses with CD control, P*_{z,Gauss}, P*_{z,CD} call almost reach linear scaling, i.e.

$${P}_{z , Gauss}^{*} , {P}_{z , CD}^{*} ∝ \frac{{κ}_{1}}{K} .$$

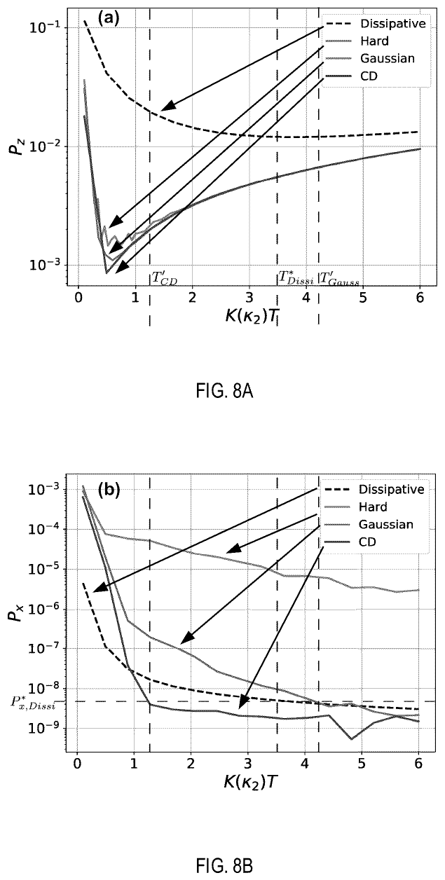

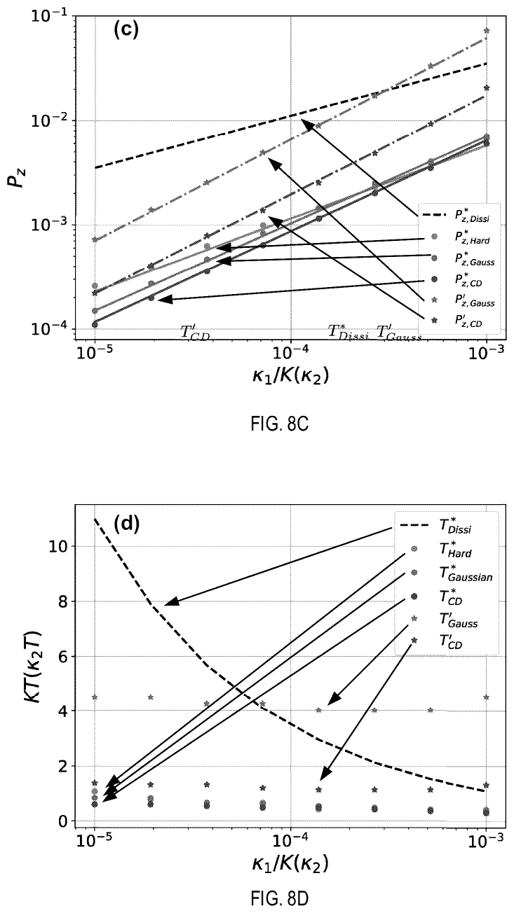

Using the fine control scheme the optimal gate fidelity decays much faster as κ₁/K decreases. As an example, the P*_{z} and T* of the CX gates at different κ₁/K(κ₂) may be numerically obtained using different control schemes shown in FIGS. 8C and 8D and the numerically fitted scalings of P*_{z} are summarized in Tab. 2.

For bias-preserving gates, not only their gate fidelity but also their ability to preserve the noise bias, i.e. keeping the X error rates sufficiently small, may need attention. In FIGS. 8A and 8B, the total Z and X error rates of the CX gate may be numerically obtained varying with gate time for κ₁/K(κ₂)=10⁻⁴. As can be seen in FIG. 8B, compared to the disspative cat, the X error rate of the CX gate on Kerr cat simply using hard pulse is too high (within reasonable gate time) compared to the dissipative gate. In contrast, gates with Gaussian pulses or CD control can have X error rate comparable to or even below that of the dissipative gate. But to obtain larger noise bias, longer gate time may be used than T*_{Gauss}, T*_{CD} and thus compromise a bit with the gate fidelity. In many applications the CX gate on dissipative gate is operated at T*_{dissi} to maximize the gate fidelity. The X error rate P*_{x,dissi} at T*_{dissi} of the dissipative cat may be set as reference and the gate time at which the Pₓ of the CX gates on Kerr cat reaches P*_{x,dissi} may be defined as the “BP” gate time T′. T′_{Gauss}, T′_{CD} as well as the corresponding P′_{z,Gauss}, P′_{z,CD} may be plotted in FIGS. 8C and 8D (stars and dotted lines). Numerically, T′_{Gauss}≈4.3/K, T′_{CD}≈1.2/K, which almost do not depend on κ₁ and are mush shorter than

$${T}_{dissi}^{*} \approx \frac{0.31}{{\vert α \vert}^{2} \sqrt{{κ}_{1} {κ}_{2}}} .$$

So similar to the optimal Z error rate, P′_{z,Gauss}, P′_{z,CD} also scales almost linear with κ₁/K, maintaining the favorable scaling with κ₁. Moverover, as T′_{CD} is several times smaller than T′_{Gauss} using CD control enables even higher gate fidelity while maintaining the high noise bias.

TABLE 2
The κ₁ dependence of the optimal Z error rates P*_{z} of CX gates with
different control schemes and the ″BP″ Z error rate P′ of the CX
gate with Gaussian and CD controls at the ″BP″ gate time T′.

| Error | | | | | | |
|---|---|---|---|---|---|---|
| rates | P*_{z,dissi} | P*_{z,Hard} | P*_{z,Gauss} | P*_{z,CD} | P′_{z,Gauss} | P′_{z,CD} |
| $\begin{matrix}∝ \\ {( \frac{{κ}_{1}}{K ( {κ}_{2} )} )}^{p}\end{matrix}$ | 1/2 | 2/3 | 0.87 | 0.84 | 0.96 | 0.95 |

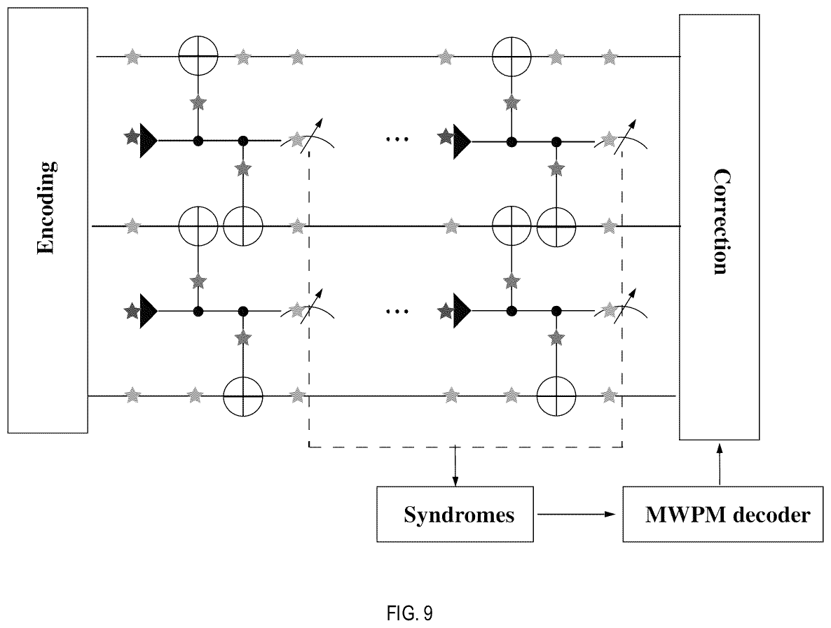

In the end, how BP gates with improved control can boose the performance of concatenated QEC in the logical level may be evaluated. A fruitful discussion on how biased-noise qubit can be concatenated with qubit codes to implement fault-tolerant quantum computation can be found. Following the same line considering the simple repetition code as the second level of encoding, the QEC circuit of the repetition cat is schematically shown in FIG. 9. A circuit-level noise model may be considered, which includes state preparation error, idling error, CX gate error and measurement error, shown by stars with different colors in FIG. 9. For a distance-d repetition code, the syndrome extraction d times may be repeated followed by one round of perfect syndrome extraction in order to deal with measurement errors and decode the error syndrome using a home-made minimum weight perfect matching (MWPM) decoder. Monte Carlo (MC) simulations may be performed to obtain the logical Z error rate P_{z}^{L} of the logical qubit and analytically estimate the logical X error rate via Pₓ^{L}=2*d*(d−1)pₓ, where pₓ is the total physical X error rate of the CX gate. For simplicity, it may be assumed that the Z error rate of idling, state preparation and X-basis measurement as κ₁|α|²T_{CX} where T_{CX} is the CX gate time and the X error rate during the idling is negligible compared that of the CX gate. For certain configuration of physical error rates, it may be kept increasing of the distance of the code to reduce P_{z}^{L} until it balances with Pₓ^{L} to obtain the lowest logical error rate P*_{L} achievable by the repetition cat. For certain κ₁/K(κ₂), the gate time may be chosen as follows: for dissipative cat, T_{CX,dissi} is chosen as T*_{dissi} which maximizes the CX gate fidelity; for Kerr cat with Gaussian and CD control, T_{CX,Gauss}, T_{CX,CD} may be chosen as T′_{Gauss}, T′_{CD}, which are the “BP” gate time giving the same X error rate as the dissipative CX gate; for Kerr cat with hard pulse, the gate time may be numerically scanned to find the one that maximizes the total logical error rate.

For the dissipative cat and the Kerr cat with Gaussian, CD control, the logical Z error rate from numerical results may be fit as:

$${P}_{z , dissi}^{L} ( {κ}_{1} / {κ}_{2} , d ) = 0.089 {( 192 \frac{{κ}_{1}}{{κ}_{2}} )}^{\frac{d + 1}{4}} \qquad ( 14 )$$

$${P}_{z , CD}^{L} ( {κ}_{1} / K , d ) = 0.086 {( 454 \frac{{κ}_{1}}{K} )}^{\frac{d + 1}{2}}$$

$${P}_{z , Gauss}^{L} ( {κ}_{1} / K , d ) = 0.086 {( 1627 \frac{{κ}_{1}}{K} )}^{\frac{d + 1}{2}}$$

The logical error rate can be estimated by:

$$\begin{matrix}{P}_{x , dissi}^{L} ( {κ}_{1} / {κ}_{2} , d ) = {P}_{x , Gauss}^{L} ( {κ}_{1} / K , d ) = {P}_{x , CD}^{L} ( {κ}_{1} / K , d ) \\ = 2 d ( d - 1 ) {p}_{x} ( {κ}_{1} / {κ}_{2} ( K ) )\end{matrix} \qquad ( 15 )$$

$$where {p}_{x} ( {κ}_{1} / {κ}_{2} ) = ( 5.58 \sqrt{\frac{{κ}_{1}}{{κ}_{2}}} + 1.568 \frac{{κ}_{1}}{{κ}_{2}} exp ( - 2 {\vert α \vert}^{2} )$$

is the physical error of the CX gate extracted, agreeing well with the simulations.

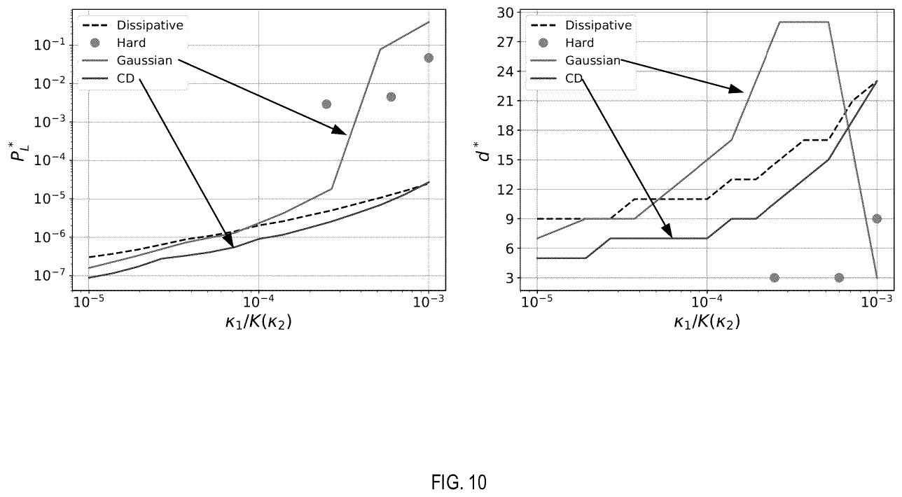

FIG. 10 shows that using CX gate on Kerr cat with the fine control scheme, lower logical error rate with smaller codes compared to using dissipative CX gate may be realized. In dramatic contrast, if the CX gate on Kerr cat with simple hard pulses is used, the logical error rate is much higher due to lower noise bias.

### Implementation Architecture

Based on the improvement of BP gates on Kerr cat in various embodiments in the present disclosure, an experimental architecture may be used that hybrids the Kerr nonlinearity with engineered two-photon dissipation to better protect the cat qubit. The Kerr nonliearity can be used to implement high fidelity gates while maintaining the high noise bias (with the fine control presented in various embodiments in the present disclosure), while the engineered two-photon dissipation provides autonomous quantum error correction that can be switched when not performing quantum gates. Such a hybrid design of both Kerr and dissipative controls may benefit from the best performance from both schemes.

As theoretically proposed and experimentally implemented, the Kerr non-linear oscillator can be implemented with Josephson effect that has fourth-order non-linearity and support three- and four-wave mixing. The two-photon dissipation, as proposed, can be implemented by parametrically coupling the non-linear Kerr oscillator to a dump cavity with low quality. The phase and amplitude of the two-photon drive should be carefully adjusted to make sure that the system stabilizes the cat states. The two-photon dissipation should be turned on when the cat is idling to keep the system sufficiently cool while turned off when implementing the the BP gates in order to enable fast gate operation (the major result of this work).

In some embodiments, a strong Kerr nonlinearity K/2π≈6.7 MHZ may be engineered but with short single-photon decay time T₁≈15.5 μs, which corresponds the dismensionless parameter κ₁/K≈1.5*10⁻³. As estimated from this work, for this value of κ₁/K the achieveable logical error rate P_{L} of the repetition cat is around 5*10⁻⁵. Experimentally, it may have very long lived superconducting cavities (T₁>1 ms) and Kerr nonlinearity up to 2π×10 MHz. So it is promising that κ₁/K may be further reduced. If κ₁/K can be reduced by 10 times, P_{L} can reach 10⁻⁶.

### Intermediate Summary

Compared to the non-unitary BP gates on dissipative cat, the originally proposed BP gates on kerr cat using hard pulses can be of high gate fidelity yet less bias-preserving since their non-adiabtic Z errors are smaller while X errors are larger. Derivation based transition suppression technique may be used to suppress the leakage of the BP gates on Kerr cat so that both the non-adiabatic Z and X errors can be reduced dramatically. In the presence of photon loss, compared to the dissipative gates the BP gates on kerr cat using a fine control scheme may have higher gate fidelity while maintaining similar noise bias. The improved gate, when applied in concatenated QEC, can lead to lower logical error rate with lower resource overhead.

### The Shifted Fock Basis and the Kerr-cat Eigenbasis

Simulating a large cat qubit using the usual fock basis is inefficient due to the wide photon number distribution of a large coherent state. In contrast, one can work with the so called shifted fock basis, to simplify the analysis since typically only the first few excitated states are populated. The shifted basis is defined as:

|ϕₙ, ± [symbol] ≡ [symbol] [\hat{D}(α)±(−1)ⁿ\hat{D}(−α)]|n [symbol] (16)

In this basis, the Hilbert space is split into two subspaces, labeled by the photon number parity + (even) and − (odd), respectively. Thus, each shifted fock state may be effectively represented as a tensor product of a parity qubit labeling the parity and a fock state labeling the excitation level:

|p [symbol] ⊗|n′ [symbol] ≡|ϕₙ, p [symbol] (17)

As the information of the two-component is encoded in the parity of its ground states, this parity can also be viewed as a “logical” qubit carrying the encoded information. These shifted fock states are not exactly mutual orthogonal. But they are nearly orthogonal for n<|α|²/4. The non-orthogonality may be neglected for now when analyzing the low excited states. In this shifted fock basis, the annilation operator can be expressed as:

â=\hat{Z}⊗(\hat{a}′+α) (18)

where \hat{Z} flips the phase of the “logical” qubit (or flips the parity of the parity qubit) and â′=Σ′ₙ\sqrt{n′}|n′−1 [symbol] [symbol] n′| is the bosonic annilation operator defined on the exication level of the shifted fock states. Based on this representation of â, the Hamiltonian of a Kerr-cat qubit may be written as:

$$\begin{matrix}{H}_{KCQ} = - K ( {a}^{2 †} - {α}^{2} ) ( {a}^{2} - {α}^{2} ) \\ = - KI ⊗ [ 4 {α}^{2} {a}^{′†} {a}^{′} + 2 α ( {a}^{′2†} {a}^{′} + {a}^{′†} {a}^{′2} ) + {a}^{′ 2 †} {a}^{′2} ]\end{matrix} \qquad ( 19 )$$

Various embodiments in the present disclosure may focus on the cat qubits protected by this strong Kerr Hamiltonian. Therefor, it is desirable to calculate the eigenspectrum and eigenstates of this Hamiltonian. Next the static perturbation theory may be used to calculate the Kerr-cat eigenstates in the shifted fock basis. The Kerr Hamiltonian preserves the photon number parity and in the large α limit Ĥ_{KCQ} is dominantly given by −KI⊗4α²â′^{†}â′. So the eigenstates of Ĥ_{KCQ} may be expressed as |ψₙ [symbol] =|p [symbol] ⊗|n″ [symbol] . |n″ [symbol] with respect to

$$\frac{1}{α}$$

may be perturbatively calculated as:

$$\vert {0}^{″} 〉 = \vert {0}^{′} 〉 \qquad ( 20 )$$

$$\vert {1}^{″} 〉 = \vert {1}^{′} 〉 - \frac{\sqrt{2} α}{2 {α}^{2} + 1} \vert {2}^{′} 〉 + 𝒪 ( {( \frac{1}{α} )}^{2} )$$

$$\vert {2}^{″} 〉 = \vert {2}^{′} 〉 + \frac{\sqrt{2} α}{2 {α}^{2} + 1} \vert {1}^{′} 〉 - \frac{\sqrt{3} α}{{α}^{2} + 1} \vert {3}^{′} 〉 + 𝒪 ( {( \frac{1}{α} )}^{2} )$$

If the first three pair of excited states are considered, i.e., n′<=2, â′ may be expressed as:

â′=σ_{0,1}⁻+\sqrt{2}σ_{1,2}⁻−λ₁Π₁−λ₂Π₂+ησ_{0,2}⁻ (21)

where

$${λ}_{1} , {λ}_{2} , η = \frac{2 α}{2 {α}^{2} + 1} , \frac{3 α}{{α}^{2} + 1} , \frac{\sqrt{2} α}{2 {α}^{2} + 1} + 𝒪 ( {( \frac{1}{α} )}^{2} ) .$$

where the reduced pauli operators and projectors are defined as:

σ_{i,j}⁻≡|i″ [symbol] [symbol] j″|

Πᵢ≡|i″ [symbol] [symbol] i″| (22)

λ₁, λ₂, η can be calculated more accurately by adding higher-order corrections. For α=\sqrt{8} used in various embodiments in the present disclosure, the below may be numerically obtained:

λ₁=0.4, λ₂=1.08, η=0.256 (23)

### Estimation of Off-resonant Excitation via Fourier Analysis

The off-resonant excitations can usually be approximately estimated via the Fourier analysis in the asymptotic weak-drive limit. As an example, a two level system that is off-resonantly driven may be considered:

\hat{H}(t)=Δ|1 [symbol] [symbol] 1|+Ω(t)(|0 [symbol] [symbol] 1|+|1 [symbol] [symbol] 0|) (24)

The propagator in the interaction picture is give by:

Û_{I}(t)= [symbol] exp [−i∫₀^{t}dt′Ω(t′)(|0 [symbol] [symbol] 1|e^{iΔt′}+h.c.)] (25)

where [symbol] is the time-ordering operator. For a weak drive, U_{I}(t) is dominantly given by the first-order dyson expansion:

Û_{I}⁽¹⁾(t)=−i∫₀^{t}dt′Ω(t′)(|0 [symbol] [symbol] 1|e^{iΔt′}+h.c.) (26)

then at certain time T the off-resonant transition strength is given by the finite-time Fourier transform of Ω(t):

[symbol]

1|Û_{I}⁽¹⁾(T)|0 [symbol] = [symbol] (Ω, Δ, T)≡∫₀^{T}Ω(t)e^{iΔt}dt (27)

and the population in the excited state is given by | [symbol] (Ω, Δ, t)|².

This finite-time Fourier transform can be connected to the standard Fourier transform by assuming Ω(t) is truncated outside the [0,t] time window or Ω(t) smoothly vanishes outside [0,t], which is usually the case for a gate pulse that starts and ends at 0.

For a pulse whose time derivatives also start and end at 0 up to order m, its Fourier spectrum has the property that:

$$ℱ ( Ω , Δ , T ) = {( - i )}^{n} ℱ ( \frac{\frac{{d}^{n}}{{dt}^{n}} Ω ( t )}{{Δ}^{n}} ) \qquad ( 28 )$$

for n=1, 2, . . . m+1. Moreover, the fourier spectrum of the product of higher-order derivatives of Ω can be converted to the fourier spectrum of higher-order polynomials of Ω:

$$ℱ ( ( Ω ( t ) ) \sum {n}_{k} , Δ , T ) = Θ ( ℱ ( {\prod }_{k} {( \frac{1}{{Δ}^{k}} \frac{{d}^{k} Ω ( t )}{{dt}^{k}} )}^{{n}_{k}} , Δ , T ) ) \qquad ( 29 )$$

Based on this, for an arbitrary smooth driving pulse Ω(t), one can add its higher-order derivatives

$$\{ \frac{{d}^{n}}{{dt}^{n}} Ω ( t ) \}$$

to create “spectral holes” at one or more gap frequencies. In general, to create N holes at frequencies Δ₁, Δ₂, . . . Δ_{N}, one can simply modify Ω(t) as:

$${Ω}^{′} = {Ω}_{0} - i {\sum }_{k} \frac{{\partial }_{t} {Ω}_{0}}{{Δ}_{k}} - {\sum }_{k} {\sum }_{j < k} \frac{{\partial }_{t}^{2} {Ω}_{0}}{{Δ}_{k} {Δ}_{j}} + … + \frac{{( - 1 )}^{N} {\partial }_{t}^{N} {Ω}_{0}}{{Δ}_{1} {Δ}_{2} … {Δ}_{N}} \qquad ( 30 )$$

provided that the first N−1 derivatives of Ω(t) start and end at 0.

This is the classical picture how derivative-based approach, which will be discussed in the next section, can be applied to eliminate off-resonant transition at certain gap frequencies. To facilitate the perturbative analysis used throughout this work, the order of the off-resonant transition strength with respect to a drive pulse Ω(t) and an energy gap Δ may be defined in the following way:

$${ϵ}^{( n )} ∝ {\vert ℱ ( \frac{{Ω}^{n}}{{Δ}^{n - 1}} , Δ , T ) \vert}^{2} \qquad ( 31 )$$

which coincides with the more conventional defination

$${ϵ}^{( n )} ∝ {( \frac{{Ω}_{0}}{Δ} )}^{n}$$

if Ω(t) is a hard (square) pulse that has the amplitude Ω₀.

Eq. 31 may be used to estimate the errors of the gate using two type of pulses considered in various embodiments in the present disclosure, one is the hard (square) pulse

$${Ω}_{h} ( t ) = \frac{π}{T}$$

and the other is the truncated Gaussian pulses:

$${Ω}_{G , m} ( t ) = {A}_{m} {\{ exp [ - \frac{{( t - T / 2 )}^{2}}{2 {σ}^{2}} ] - exp [ - \frac{{( T / 2 )}^{2}}{2 {σ}^{2}} ] \}}^{m} \qquad ( 32 )$$

The first-order excitation at gap energy Δ using the hard pulse is:

$${ϵ}_{h}^{( 1 )} ( T ) ∝ {\vert ℱ ( {Ω}_{h} , Δ , T ) \vert}^{2} = 4 \frac{{sin}^{2} Δ T}{{( Δ T )}^{2}} \qquad ( 33 )$$

which scales quadratic with 1/ΔT and accounts for the non-adiabatic gate errors using hard pulse in the main text.

The first-order and second-order excitation at gap energy Δ using the truncated Gaussian pulse are:

$${ϵ}_{G , m}^{( 1 )} ( T ) ∝ {\vert ℱ ( {Ω}_{G , m} , Δ , T ) \vert}^{2} , {ϵ}_{G , m}^{( 2 )} ( T ) ∝ {\vert ℱ ( \frac{{Ω}_{G , m}^{2}}{Δ} , Δ , T ) \vert}^{2} \qquad ( 34 )$$

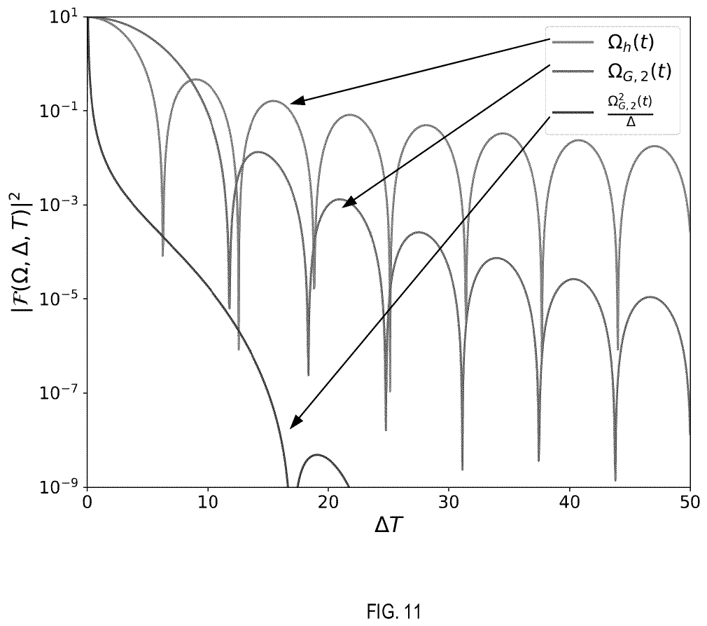

Their analytical expressions are lengthy, so instead they may be numerically plotted in FIG. 11. As shown by the green curve, ϵ_{G,m}⁽¹⁾(T) first decreases exponentially with T in the short-T regime as a result of being Gaussian pulse and then scales with T in power law due to the truncation effect in the long-T regime. For ϵ_{G,m}⁽²⁾(T) shown by the blue line, the scaling with T can be approximately exponential until the regime where the spectrum weight is sufficiently small.

### Derivative-based Transition Suppression

In this section the technique of derivative-based transition suppression that is used in various embodiments in the present disclosure may be summarized.

The general task in some implementations is to apply quantum control to a multi-level quantum system, whose Hilber space is in the following form: [symbol] = [symbol] _{logical}⊕ [symbol] ₗₑₐₖ, where [symbol] _{logical} is the logical subspace inside which the system stays while [symbol] ₗₑₐₖ is the subspace which the system is prevented from leaking into. \hat{P} may be defined as the projector onto [symbol] _{logical} while \hat{Q} as the complementary projector onto [symbol] ₗₑₐₖ. The original Hamiltonian applying to generate the desired dynamics is typically in the form:

Ĥ_{original}=Ĥ₀(t)+\hat{V}(t) (35)

where Ĥ₀=\hat{P}Ĥ₀\hat{P}+\hat{Q}Ĥ₀\hat{Q} is in the block-diagonal form while \hat{V}=\hat{P}V\hat{P}+\hat{Q}V\hat{Q}+\hat{P}V\hat{Q}+\hat{Q}V\hat{P} inevitably couples the logical subspace to the leakage subspace while generating the desired dynamics within the logical subspace. In this case, there will be leakage from [symbol] _{logical} to [symbol] ₗₑₐₖ during the system evolution brought by the off-diagonal part of \hat{V}. In most cases of interest there is a large energy gap between [symbol] _{logical} and [symbol] ₗₑₐₖ, which is contained in H₀(t). So the leakage is associated with off-resonant, diabatic transitions. Fortunately one can modify the control Hamiltonian by applying some couterdiabatic drive H_{cd}(t) to suppress the leakage:

Ĥ_{modified}=Ĥ_{original}+Ĥ_{cd}(t) (36)

If a frame transformation that can block-diagonalize the original Hamiltonian Ĥ_{original}(t) may be easily found, it may move to this adiabatic frame defined by A(t) and calculate the effective Hamiltonian:

Ĥ_{eff}=Â(t)Ĥ_{modified}Â^{†}(t)+i\hat{\dot{A}}(t)Â^{†}(t)=Â(t)Ĥ_{original}Â^{†}(t)+Â(t)Ĥ_{cd}Â^{†}(t)+i\hat{\dot{A}}(t)Â^{†}(t) (37)

where Â(t)Ĥ_{original}Â^{†}(t)=\hat{P}Â(t)Ĥ_{original}Â^{†}(t)\hat{P}+\hat{Q}Â(t)Ĥ_{original}Â^{†}(t)\hat{Q}. And if it's able to apply the counterdiabatic term in the form Ĥ_{cd}(t)=−iÂ^{†}\hat{\dot{A}}, all the leakage in this adiabatic frame may be perfectly removed. If it further ensures that the adiabtic frame coincides with the lab frame at the beginning and the end of the gate, i.e. Â(0)=Â(T)=0 where T is the gate time, it may then successfully remove all the leakage by the end of the gate in the lab frame. However, in most realistic settings one can neither perfectly block-diagonalize Ĥ_{original}(t) nor perfectly apply the counterdiabatic term. In this case, some perturbative approach may be used.

In various embodiments in the present disclosure, the form Ĥ₀ and \hat{V} may be specified as:

Ĥ₀= [symbol] Δₘ|m [symbol] [symbol] m|

\hat{V}(t)=Ω₀(t)\hat{V}₀⁺+h.c.

\hat{V}₀⁺= [symbol] λᵢⱼ|i [symbol] [symbol] j|+ [symbol] λₘₙ|m [symbol] [symbol] n|+ [symbol] λₘᵢ|m [symbol] [symbol] i| (38)

All the diabetic transitions are controlled by a simple pulse Ω(t). For simplicity, all the diabatic transitions may be relabeled by single index k, i.e. \hat{Q}\hat{V}(t)\hat{P}=Ω₀(t)(Σₖλₖĥₖ) and denote the associated energy gaps in Ĥ₀ as Δₖ. The adiabatic parameter may be defined as

$$ϵ ≡ {max}_{k} \vert {Ω}_{0} \frac{{λ}_{k}}{{Δ}_{k}} \vert .$$

The perturbation will be based on this adiabatic parameter.

Instead of moving to the exact adiabatic frame, it now move to the so called DRAG frame defined by \hat{D}(t)=exp [iŜ(t)], where Ŝ(t)=Σⱼ₌₁Ŝ^{(j)} is expanded to different orders in ϵ. The effective Hamiltonian in this DRAG frame can be perturbatively calculated using the Schrieffer-Wolff (SW) expansion:

$$\begin{matrix}{\hat{H}}_{eff} = \hat{D} ( t ) {\hat{H}}_{modified} {\hat{D}}^{†} ( t ) + i \dot{\hat{D}} ( t ) {\hat{D}}^{†} ( t ) \\ = {\sum }_{n} {\frac{1}{n !} [ \hat{H} , - i \hat{S} ]}_{n} + {( - i )}^{n} {\sum }_{n} {\frac{1}{( n + 1 ) !} [ \dot{\hat{S}} , \hat{S} ]}_{n} \\ = {\sum }_{j = 0} {\hat{H}}_{eff}^{( j )} ( t )\end{matrix} \qquad ( 39 )$$

where [Â, \hat{B}]ₙ=[[Â, \hat{B}]ₙ₋₁, \hat{B}] and [Â, \hat{B}]₀=Â. Ĥ₀ is of order 0, \hat{V}(t) is of order 1 and Ĥ_{cd} contains corrections to different orders Ĥ_{cd}(t)=Σⱼ₌₁Ĥ_{cd}^{(j)}(t). It may explicitly list Ĥ_{eff} up to the second order below:

Ĥ_{eff}⁽⁰⁾=Ĥ₀

Ĥ_{eff}⁽¹⁾=\hat{V}+i[Ŝ⁽¹⁾, Ĥ₀]+Ĥ_{cd}⁽¹⁾+\hat{\dot{S}}⁽¹⁾

Ĥ_{eff}⁽²⁾=i[Ŝ⁽²⁾, Ĥ₀]+i[Ŝ⁽¹⁾, \hat{V}+Ĥ_{cd}⁽¹⁾]−½[Ŝ⁽¹⁾, [Ŝ⁽¹⁾, Ĥ₀]]+Ĥ_{cd}⁽²⁾+\hat{\dot{S}}⁽²⁾−i[\hat{\dot{S}}⁽¹⁾, Ŝ⁽¹⁾] (40)

In various embodiments in the present disclosure, the leakage error may be only corrected to the first order, i.e. \hat{Q}H_{eff}⁽¹⁾\hat{P}=0, which can be satisfied simply by shaping the control pulse:

H_{cd}⁽¹⁾(t)=u(t)\hat{V}₀⁺+h.c. (41)

where u(i) is the classical solution that corresponds to creating N “spectral holes” at N different gap energies {Δₖ}:

$$u = - i {\sum }_{k} \frac{{\partial }_{t} {Ω}_{0}}{{Δ}_{k}} - {\sum }_{k} {\sum }_{j < k} \frac{{\partial }_{t}^{2} {Ω}_{0}}{{Δ}_{k} {Δ}_{j}} + … + \frac{{( - i )}^{N} {\partial }_{t}^{N} {Ω}_{0}}{{Δ}_{1} {Δ}_{2} … {Δ}_{N}} \qquad ( 42 )$$

and the corresponding first order DRAG frame-transformation is given by: And the corresponding first-order frame transformation is:

$${\hat{S}}^{( 1 )} = i {\sum }_{k} \frac{{Δ}_{0}}{{Δ}_{k}} {\hat{h}}_{k} + {\sum }_{k} {\sum }_{j \neq k} \frac{{\partial }_{t} {Ω}_{0}}{{Δ}_{j} {Δ}_{k}} {\hat{h}}_{k} - {\sum }_{k} {\sum }_{j \neq k} {\sum }_{i \neq k , k} \frac{{\partial }_{t}^{2} {Ω}_{0}}{{Δ}_{i} {Δ}_{j} {Δ}_{k}} {\hat{h}}_{k} … + \frac{( - 1 ) {( - i )}^{N} {\partial }_{t}^{N - 1} {Ω}_{0}}{{Δ}_{1} {Δ}_{2} … {Δ}_{N}} {\hat{h}}_{k} + h . c . \qquad ( 43 )$$

The leakage error is then suppressed to the second order, i.e.

$$𝒪 ( {\vert ℱ ( \frac{{Ω}_{0}^{2}}{Δ} , Δ , T ) \vert}^{2} ) .$$

However, although the leakage error brought by the higher-order terms is smaller than the original first-order leakage, there will phase or rotation errors acting on the logical subspace directly resulting from those higher-order expansions. As these terms are not associated with any energy gap, their countribution can be comparable or even larger than the original first-order leakage error. To deal with these errors, Ĥ_{eff} (or higher-order terms) given Ŝ⁽¹⁾ and Ĥ_{cd}⁽¹⁾ may be calculated and high order corrections to Ĥ_{cd} may be added. It may not give a general strategy here but rather give corresponding corrections when concretely discussing different gates.

### Derivation of the Counterdiabatic Controls

### Z Rotation

The original Hamiltonian implementing a Z rotation on single cat is:

Ĥ_{original}=Ĥ₀+\hat{V}=−Kₕ(â^{2†}−α²)(â²−α²)+Ωₓ(t)(â+â^{†}) (44)

where Ĥ₀=−Kₕ(â^{2†}−α²)(â²−α²) and \hat{V}=Ωₓ(t)(â+â^{†}). By adding counterdiabatic terms in the form Ĥ_{cd}(t)=uₓ(t)(â+â^{†})+iu_{y}(t)(â−â^{†}), the modified control Hamiltonian may be expressed as:

Ĥ_{modified}=Kₕ(â^{2†}−α²)(â²−α²)+[Ωₓ(t)+uₓ(t)](â+â^{†})+iu_{y}(t)(â−â^{†}) (45)

Working in the eigenbasis of the Kerr-cat Hamiltonian and only considering the first three pair of eigenstates, Ĥ_{modified} may be expressed as:

Ĥ_{modified}≈Î⊗(Δ₁\hat{Π}₁+Δ₂\hat{Π}₂)+2α(Ωₓ+uₓ)\hat{Z}⊗[\hat{Π}₀+(1−λ₁)\hat{Π}₁+(1−λ₂\hat{Π}₂)]+(Ωₓ+uₓ)\hat{Z}⊗(\hat{σ}_{0,1}^{x}+\sqrt{2}σ_{1,2}^{x}+η_{0,2}\hat{σ}_{0,2}^{x})+iu_{y}Z⊗(\hat{σ}_{0,1}^{y}+\sqrt{2}σ_{1,2}^{y}+η_{0,2}\hat{σ}_{0,2}^{y}) (46)

There are two diabatic transitions Z⊗\hat{σ}_{0,1}⁺, Z⊗\hat{σ}_{0,2}⁻ that come from the same linear drive, associated with two gap frequencies Δ₁, Δ₂ respectively. So the classical solution Eqs. 42 and 43 may be applied to suppress first-order leakage by setting the DRAG transformation:

$${\hat{S}}^{( 1 )} ( t ) = {Ω}_{x} \hat{Z} ⊗ ( \frac{1}{{Δ}_{1}} {\hat{σ}}_{0 , 1}^{y} + \frac{1}{{Δ}_{1}} {σ}_{1 , 2}^{y} + \frac{1}{{Δ}_{2}} {η}_{0.2 .} {σ}_{0 , 2}^{y} ) + \frac{{\dot{Ω}}_{x}}{{Δ}_{1} {Δ}_{2}} Z ⊗ ( {σ}_{0 , 1}^{x} + {σ}_{1 , 2}^{x} + {η}_{0 , 2} {σ}_{0 , 2}^{x} ) \qquad ( 47 )$$

and the CD control pulses:

$${u}_{x}^{( 1 )} = - \frac{{\ddot{Ω}}_{x} ( t )}{{Δ}_{1} {Δ}_{2}} \qquad ( 48 )$$

$${u}_{y}^{( 1 )} = - {\ddot{Ω}}_{x} ( t ) ( \frac{1}{{Δ}_{1}} + \frac{1}{{Δ}_{2}} )$$

where the base driving pulse Ωₓ(t)=Ω_{G,2}(t) is chosen to make sure that Ωₓ, \dot{Ω}ₓ start and end at 0. Then it can block-diagonalize Ĥ_{eff}⁽¹⁾, i.e., \hat{P}Ĥ_{eff}⁽¹⁾\hat{P}=2αΩₓ(t)\hat{Z}⊗Π₀, \hat{P}H_{eff}⁽¹⁾\hat{Q}=0. The residual error is then of order

$$𝒪 ( {\vert ℱ ( \frac{{Ω}_{x}^{2}}{Δ} , Δ , T ) \vert}^{2} )$$

which come from H_{eff}⁽²⁾ and higher order expansions. In addition to the leakage error, however, there will be terms from H_{eff}⁽³⁾ (and higher-order expansions) that cause over-rotation (\hat{Z}⊗Π₀). The over-rotation angle is given by

$$δθ ∝ ℱ ( \frac{{Ω}_{x}^{3}}{{Δ}_{1}^{2}} , 0 , T ) ,$$

which can be corrected by re-normalize the rotation angle or adding addition term to uₓ:

$${u}_{x} ( t ) = {u}_{x}^{( 1 )} + {c}_{0} \frac{{Ω}_{x}^{3} ( t )}{{Δ}_{1}^{2}} \qquad ( 49 )$$

In the present disclosure, instead of doing lengthy calculations, it simply numerically optimizes c₀ to obtain c₀≈0.70.

### ZZ Rotation

The original Hamiltonian implementing a ZZ rotation on two cats is:

H_{original}(t)=H₀+V(t)

H₀=−K(â_{c}^{2†}−α²)(â_{c}²−α²)−K(âₜ^{2†}−α²)(âₜ²−α²)

V(t)=Ωₓ(t)(â_{c}âₜ+â_{c}^{†}âₜ^{†}) (50)

By adding conterdiabatic terms in the form Ĥ_{cd}(t)=uₓ(t)(â_{c}âₜ+â_{c}^{†}âₜ^{†})+iu_{y}(t)(â_{c}âₜ−â_{c}^{†}âₜ^{†}), the modified control Hamiltonian may be expressed as:

H_{modified}=−K(â_{c}^{2†}−α²)(â_{c}²−α²)−K(âₜ^{2†}−α²)(âₜ²−α²)+[Ωₓ(t)+uₓ(t)](â_{c}âₜ+â_{c}^{†}âₜ^{†})+iu_{y}(t)(â_{c}âₜ−â_{c}^{†}âₜ^{†}) (51)

Working in Kerr-cat eigenbasis and only considering the first three pair of eigenstates for each mode, H_{modified} may be expressed as:

$${H}_{0} = {Δ}_{1} ( {Π}_{1}^{c} + {Π}_{1}^{t} ) + {Δ}_{2} ( {Π}_{2}^{c} + {Π}_{2}^{t} ) \qquad ( 52 )$$

$$\hat{P} V ( t ) \hat{P} + \hat{P} V ( t ) \hat{Q} + \hat{Q} V ( t ) \hat{P} = 2 {α}^{2} ( {Ω}_{x} + {u}_{x} ) {Z}_{c} {Z}_{t} ⊗ {Π}_{0} + ( {Ω}_{x} + {u}_{x} ) {Z}_{c} {Z}_{t} ⊗ [ α ( {σ}_{0 , 1}^{x , c} + {σ}_{0 , 1}^{x , t} ) + {σ}_{1 , 2}^{x , t} ) + η α ( {σ}_{0 , 2}^{x , c} + {σ}_{0 , 2}^{x , t} ) + {σ}_{00 , 11}^{x} + η ( {σ}_{00 , 12}^{x} + {σ}_{00 , 21}^{x} ) + {η}_{00 , 22}^{x} ] + i {u}_{y} {Z}_{c} {Z}_{t} ⊗ [ α ( {σ}_{0 , 1}^{y , c} + {σ}_{0 , 1}^{y , t} ) + {σ}_{1 , 2}^{y , t} ) + η α ( {σ}_{0 , 2}^{y , c} + {σ}_{0 , 2}^{y , t} ) + {σ}_{00 , 11}^{y} + η ( {σ}_{00 , 12}^{y} + {σ}_{00 , 21}^{y} ) + {η}^{2} {σ}_{00 , 22}^{y} ]$$

where only the projection of \hat{V}(t) in [symbol] _{logical} and its block off-diagonal part are shown for simplicity.

TABLE 3
The dominant diabatic transitions of the ZZ gate and their associated energy
gaps. Here the fact that Δ₂ ≈ 2Δ₁ may be used.

| | | | |
|---|---|---|---|
| Transition | Z_{c}Zₜ ⊗ | Z_{c}Zₜ ⊗ | Z_{c}Zₜ ⊗ |
| | (σ_{0, 1}^{+, c}, σ_{0, 1}^{+, t}) | (σ_{0, 2}^{+, t}, σ_{0, 2}^{+, c}, σ_{00, 11}⁺) | (σ_{00, 12}⁺, σ_{00, 21}⁺) |
| Energy gap | Δₐ ≡ Δ₁ | Δ_{b} ≡ 2Δ₁(Δ₂) | Δ_{c} ≡ Δ₁ + Δ₂ |

In the present disclosure, three group of diabatic transitions associated with three energy gaps Δₐ, Δ_{b}, Δ_{c} that all come from the two-mode squeezing are considered, listed in Tab. 3. Similar to the Z rotation, it can also apply the classical solution Eqs. 42 and 43 to suppress first-order leakage to these excited states by setting the DRAG transformation:

$${\hat{S}}^{( 1 )} = \frac{{Ω}_{x}}{{Δ}_{a}} {\hat{Y}}_{a} + \frac{{Ω}_{x}}{{Δ}_{b}} {\hat{Y}}_{b} + \frac{{Ω}_{x}}{{Δ}_{c}} {\hat{Y}}_{c} + \frac{{\dot{Ω}}_{x}}{{Δ}_{a}} ( \frac{1}{{Δ}_{a}} + \frac{1}{{Δ}_{c}} ) {\hat{X}}_{a} + \frac{{\dot{Ω}}_{x}}{{Δ}_{b}} ( \frac{1}{{Δ}_{b}} + \frac{1}{{Δ}_{c}} ) {\hat{X}}_{b} + \frac{{\dot{Ω}}_{x}}{{Δ}_{c}} ( \frac{1}{{Δ}_{c}} + \frac{1}{{Δ}_{c}} ) {\hat{X}}_{c} + \frac{{\ddot{Ω}}_{x}}{{Δ}_{a} {Δ}_{b} {Δ}_{c}} ( {\hat{Y}}_{a} + {\hat{Y}}_{b} + {\hat{Y}}_{c} ) \qquad ( 53 )$$

where

\hat{X}ₐ=Z_{c}Zₜ⊗[α(σ_{0,1}^{x,c}+σ_{0,1}^{x,t})+\sqrt{2}α(σ_{1,2}^{x,c}+σ_{1,2}^{x,t})+ηα(σ_{0,2}^{x,c}+σ_{0,2}^{x,t})

\hat{X}_{b}=Z_{c}Zₜ⊗[σ_{00,11}^{x}+ηα(σ_{0,2}^{x,c}+σ_{0,2}^{x,t}]

\hat{X}_{b}=Z_{c}Zₜ⊗[η(σ_{00,12}^{x}+σ_{00,21}^{x})+η²σ_{00,22}^{x}] (54)

and the CD control pulses:

$${u}_{x}^{( 1 )} ( t ) = - {\ddot{Ω}}_{0} ( t ) ( \frac{1}{{Δ}_{a} {Δ}_{b}} + \frac{1}{{Δ}_{a} {Δ}_{c}} + \frac{1}{{Δ}_{b} {Δ}_{c}} ) \qquad ( 55 )$$

$${u}_{y}^{( 1 )} ( t ) = - {\dot{Ω}}_{0} ( t ) ( \frac{1}{{Δ}_{a}} + \frac{1}{{Δ}_{b}} + \frac{1}{{Δ}_{c}} ) + \frac{{\ddot{Ω}}_{0} ( t )}{{Δ}_{a} {Δ}_{b} {Δ}_{c}}$$

Then the diabatic transitions are suppressed to the second order

$$O ( {\vert ℱ ( \frac{{Ω}_{x}^{2}}{Δ} , Δ , T ) \vert}^{2} ) .$$

Similar to the Z rotation, there will be an over-rotation Z_{c}Zₜ⊗Π₀^{c}Π₀^{t} coming from the higher-order DRAG expansion, which can be compensated by rescaling the rotation angle or adding an additional term to uₓ:

$${u}_{x} ( t ) = {u}_{x}^{( 1 )} + {c}_{0} \frac{{Ω}_{x}^{3} ( t )}{{Δ}_{a}^{2}} \qquad ( 56 )$$

where c₀ may be numerically optimized to obtain c₀≈0.126.

### CX Gate

The original Hamiltonian for the CX gate is:

$${\hat{H}}_{original} ( t ) = {\hat{H}}_{KPO}^{( c )} + {\hat{H}}_{KPO}^{( t )} + {\hat{H}}_{cp} \qquad ( 57 )$$

$${\hat{H}}_{KPO}^{( c )} = - K ( {\hat{a}}_{c}^{†2} - {α}^{2} ) ( {\hat{a}}_{c}^{2} - {α}^{2} )$$

$${\hat{H}}_{KPO}^{( t )} ( t ) = - K [ {\hat{a}}_{t}^{†2} - {α}^{2} {e}^{- 2 i ϕ ( t )} ( \frac{α - {\hat{a}}_{c}^{†}}{2 α} ) - {α}^{2} ( \frac{α - {\hat{a}}_{c}^{†}}{2 α} ) ] \times [ \text{} {\hat{a}}_{t}^{2} - {α}^{2} {e}^{2 i ϕ ( t )} ( \frac{α - {\hat{a}}_{c}}{2 α} ) - {α}^{2} ( \frac{α + {\hat{a}}_{c}}{2 α} ) ]$$

$${H}_{cp} = - \frac{1}{2} ϕ \frac{( 2 α - {\hat{a}}_{c}^{†} - {\hat{a}}_{c} )}{2 α} ( {\hat{a}}_{t}^{†} {\hat{a}}_{t} - {α}^{2} )$$

The operators on the control mode may be represented in the shifted fock basis and Ĥ_{KPO}^{(c)} and Ĥ_{cp} may be expressed as:

$${H}_{KPO}^{( t )} = - K [ {a}_{t}^{2 †} - {α}^{2} {e}^{- 2 i ϕ} {P}_{c}^{-} - {α}^{2} {P}_{c}^{+} + \frac{1}{2} α ( {e}^{- 2 i ϕ} - 1 ) {Z}_{c} ⊗ {a}_{c}^{′†} ] [ \text{} {a}_{t}^{2} - {α}^{2} {e}^{2 i ϕ} {P}_{c}^{-} - {α}^{2} {P}_{c}^{+} + \frac{1}{2} α ( {e}^{2 i ϕ} - 1 ) {Z}_{c} ⊗ {a}_{c}^{′} ] c \qquad ( 58 )$$

$${H}_{cp} = - ϕ [ {P}_{c}^{-} - \frac{1}{4 α} ( {a}_{c}^{′} + {a}_{c}^{′†} ) ] ( {a}_{t}^{†} {a}_{t} - {α}^{2} )$$

$$where$$

$${P}_{c}^{+} ≡ \frac{{I}_{c} + {z}_{c}}{2}$$

$$and$$

$${P}_{c}^{-} ≡ \frac{{I}_{c} - {z}_{c}}{2} .$$

The following adiabatic frame may be defined as

U(t)=exp [−i∫₀^{t}dt′\dot{ϕ}(t′)P_{c}⁻⊗(aₜ^{†}aₜ−α²)]=P_{c}⁻⊗exp [−iϕ(t)(aₜ^{†}aₜ−α²)]+P_{c}⁺ (59)

and obtain the Hamiltonian in the adiabatic frame as:

$${\tilde{H}}_{original} ( t ) = U ( t ) {H}_{original} {U}^{†} ( t ) + i \dot{U} ( t ) {U}^{†} ( t ) = {\tilde{H}}_{0} + {\tilde{H}}_{υ} + \tilde{V} \qquad ( 60 )$$

$${\tilde{H}}_{0} = - K ( {a}_{t}^{2 †} - {α}^{2} ) ( {a}_{t}^{2} - {α}^{2} ) - K ( {a}_{c}^{2 †} - {α}^{2} ) ( {a}_{c}^{2} - {α}^{2} ) - \frac{1}{2} K {α}^{2} ( 1 - cos 2 ϕ ) {I}_{c} {a}_{c}^{′†} {a}_{c}^{′}$$

$${\tilde{H}}_{υ} = - \frac{1}{2} K α [ i sin 2 ϕ {Z}_{c} - ( 1 - cos 2 ϕ ) {I}_{c} ] ⊗ {a}_{c}^{′} ( {a}_{t}^{2 †} - {α}^{2} ) + h . c .$$

$$\tilde{V} = \frac{1}{4 α} ϕ {Z}_{c} ( {a}_{c}^{′} + {a}_{c}^{′†} ) ⊗ ( {a}_{t}^{†} {a}_{t} - {α}^{2} )$$

Only considering the first two pairs of excited states and expressing the annilation operator in the Kerr-cat eigenbasis a_{c,t}=Z_{c,t}⊗(α+σ_{0,1}^{-,c,t}−λ₁Π₁^{c,t}) in the Kerr-cat eigenbasis. Then the Hamiltonian Eq. 60 may be expressed as:

$${\tilde{H}}_{0} = {Δ}_{1} {I}_{t} ⊗ {\prod }_{1}^{t} + [ {Δ}_{1} - \frac{1}{2} K {α}^{2} ( 1 - cos 2 ϕ ) ] {I}_{c} ⊗ {\prod }_{1}^{c} + 2 K {α}^{2} {λ}_{1}^{2} ( 1 - cos 2 ϕ ) {I}_{c} {I}_{t} ⊗ {\prod }_{1}^{c} {\prod }_{1}^{t} \qquad ( 61 )$$

$${\tilde{H}}_{υ} \approx K {α}^{2} ( 1 - cos 2 ϕ ) {I}_{c} {I}_{t} ⊗ [ {σ}_{01 , 10}^{x} - {λ}_{1} ( {\prod }_{1}^{c} {σ}_{0 , 1}^{x , t} + {σ}_{0 , 1}^{x , c} {\prod }_{1}^{t} ) ] - K {α}^{2} sin 2 ϕ {Z}_{c} {I}_{t} ⊗ [ {σ}_{01 , 10}^{y} - {λ}_{1} ( {σ}_{0 , 1}^{y , c} {\prod }_{1}^{t} - {\prod }_{1}^{c} {σ}_{0 , 1}^{y , t} ) ]$$

$$\tilde{V} \approx \frac{1}{4} ϕ {Z}_{c} {I}_{t} ⊗ {σ}_{0.1}^{x , c} {σ}_{0.1}^{x , t}$$

In this lab frame, the dominant leakage is to Z_{c}Iₜ⊗σ_{00,11}⁺ via \tilde{V} and its associated time-dependent energy gap is

$${Δ}_{11} ( t ) = 2 {Δ}_{1} - \frac{1}{2} K {α}^{2} [ 1 - 4 {λ}_{1}^{2} ) ( 1 - cos 2 ϕ ( t ) ]$$

the first order DRAG transformation with respect to this transition may be defined as:

$${S}^{( 1 )} = - \frac{1}{4} \frac{\dot{ϕ}}{{Δ}_{11} ( t )} {Z}_{c} {I}_{t} ⊗ {σ}_{00 , 11}^{y} \qquad ( 62 )$$

To correct this leakage, it may first add

$${H}_{cd}^{( 1 )} = - i \frac{d}{dt} [ \frac{\dot{ϕ}}{{Δ}_{11} ( t )} ] ( {a}_{c} - {a}_{c}^{†} ) ⊗ ( {a}_{t}^{†} {a}_{t} - {α}^{2} )$$

and obtain the first-order effective Hamiltonian in this DRAG frame:

$$\begin{matrix}{\hat{H}}_{eff}^{( 1 )} = \hat{\tilde{V}} + i [ {\hat{S}}^{( 1 )} , {\hat{\tilde{H}}}_{0} ] + i [ {\hat{S}}^{( 1 )} , {\hat{\tilde{H}}}_{υ} ] \\ = \frac{1}{4} K {α}^{2} {λ}_{1} \frac{\dot{ϕ} ( 1 - cos 2 ϕ )}{{Δ}_{11} ( t )} {Z}_{c} {I}_{t} ⊗ ( {σ}_{0 , 1}^{x , c} {\prod }_{0}^{t} + {\prod }_{0}^{c} {σ}_{0 , 1}^{x , t} ) - \\ \frac{1}{4} K {α}^{2} {λ}_{1} \frac{\dot{ϕ} sin 2 ϕ}{{Δ}_{11} ( t )} {I}_{c} {I}_{t} ⊗ ( {\prod }_{0}^{c} {σ}_{0 , 1}^{y , t} - {σ}_{0 , 1}^{y , c} {\prod }_{0}^{t} ) - \\ \frac{1}{4} \frac{d}{dt} [ \frac{\dot{ϕ}}{{Δ}_{11} ( t )} ] {Z}_{c} {I}_{t} ⊗ {σ}_{00 , 11}^{y}\end{matrix} \qquad ( 63 )$$

To eliminate the Z_{c}Iₜ⊗σ_{00,11}⁺ transition, the standard derivative correction

$${H}_{cd , 0}^{( 1 )} = {iu}_{0} ( t ) \frac{{\hat{a}}_{c} - {\hat{a}}_{c}^{†}}{4 α} ⊗ ( {\hat{a}}_{t}^{†} {\hat{a}}_{t} - {α}^{2} )$$

may be added, where

$${u}_{0} ( t ) = \frac{d}{dt} [ \frac{\dot{ϕ}}{{Δ}_{11} ( t )} ] .$$

The remaining diabatic transitions in H_{eff}⁽¹⁾ come frome i[Ŝ⁽¹⁾, \tilde{Ĥ}ᵥ] since \tilde{Ĥ}ᵥ is not diagonal in the kerr-cat eigenbasis. So additional terms may be added to H_{cd} to suppress these transitions.

To suppress Z_{c}Iₜ⊗σ_{0,1}^{x,c}Π₀^{t}, the following may be added:

$${\hat{H}}_{cd , 1}^{( 1 )} = {c}_{1} \frac{\dot{ϕ} ( 1 - cos 2 ϕ )}{{Δ}_{11} ( t )} ( \hat{a} + {\hat{a}}^{†} ) , {c}_{1} = \frac{1}{4} K {α}^{2} {λ}_{1} \qquad ( 64 )$$

To suppress I_{c}Iₜ⊗σ_{0,1}^{y,c}Π₀^{t}, the following may be added:

$${\hat{H}}_{cd , 2}^{( 1 )} = {ic}_{2} \frac{\dot{ϕ} sin 2 ϕ}{{Δ}_{11} ( t )} ( {\hat{a}}_{c}^{2} - {\hat{a}}_{c}^{2 †} ) , {c}_{2} = \frac{1}{8} K {αλ}_{1} \qquad ( 65 )$$

Finally Z_{c}Iₜ⊗Π₀^{c}σ_{0,1}^{x,t} and I_{c}Iₜ⊗Π₀^{c}σ_{0,1}^{y,t} may be simultaneously suppressed by adding:

$${\hat{H}}_{cd , 3}^{( 1 )} = {c}_{3} \frac{\dot{θ} ( t )}{{Δ}_{11} ( t )} [ ( {e}^{2 i ϕ ( t )} - 1 ) {\hat{a}}_{t}^{2 †} + ( {e}^{- 2 i ϕ ( t )} - 1 ) {\hat{a}}_{t}^{2} ] , {c}_{3} = \frac{1}{8} K {αλ}_{1} \qquad ( 66 )$$

So in total, four CD corrections Ĥ_{cd}⁽¹⁾=Ĥ_{cd,0}⁽¹⁾+Ĥ_{cd,1}⁽¹⁾+Ĥ_{cd,2}⁽¹⁾+Ĥ_{cd,3}⁽¹⁾ may be applied to suppress the first-order leakage to the first pair of excited states of each mode.

However, by adding Ĥ_{cd,1}⁽¹⁾, it also induces extra unitary Z rotation on the control mode, which can be compensated by applying an additional Z rotation \hat{Z}(δθ) on control mode after the CX gate, which has negligible error compared to the CX gate.

Reference throughout this specification to features, advantages, or similar language does not imply that all of the features and advantages that may be realized with the present solution should be or are included in any single implementation thereof. Rather, language referring to the features and advantages is understood to mean that a specific feature, advantage, or characteristic described in connection with an embodiment is included in at least one embodiment of the present solution. Thus, discussions of the features and advantages, and similar language, throughout the specification may, but do not necessarily, refer to the same embodiment.

Furthermore, the described features, advantages and characteristics of the present solution may be combined in any suitable manner in one or more embodiments. One of ordinary skill in the relevant art will recognize, in light of the description herein, that the present solution can be practiced without one or more of the specific features or advantages of particular embodiment. In other instances, additional features and advantages may be recognized in certain embodiments that may not be present in all embodiments of the present solution.

1. A method for performing a quantum operation on a qubit using a noise-bias-preserving (NBP) quantum gate, the method comprising:
obtaining and stabilizing the qubit;
determining a type of the NBP quantum gate associated with the quantum operation; and
applying, according to the type of the NBP quantum gate, the quantum operation on the qubit to obtain a modified qubit, the quantum operation comprising a base gate drive and a counterdiabatic (CD) control drive.

2. The method according to claim 1, wherein:
the qubit comprises a Schrodinger Cat qubit comprising coherent quantum superposition of a plurality of quantum states.

3. The method according to claim 1, wherein stabilizing the qubit comprises:
stabilizing the qubit in a Kerr nonlinear oscillator with a parametric two-photon drive.

4. The method according to claim 3, wherein the Kerr nonlinear oscillator with the parametric two-photon drive is associated with a stabilization Hamiltonian satisfying:
Ĥ_{KPO}=−K(â^{2†}−α²)(â²−α²),
wherein: Ĥ_{KPO} is the Hamiltonian for the Kerr oscillator, K indicates a strength of Kerr nonlinearity, α indicates a value in phase space, and â indicates an operator.

5. (canceled)

6. The method according to claim 1, wherein:
the type of the NBP quantum gate comprises one of a Z rotation gate, a ZZ rotation gate, or a controlled-NOT (CX) gate.

7. The method according to claim 1, wherein:
the CD control drive corresponds to a set of CD control pulses designed according to the type of the NBP quantum gate.

8. The method according to claim 7, wherein:
the set of CD control pulses comprise a function of a set of truncated Gaussian pulses.

9-11. (canceled)

12. The method according to claim 1, further comprising:
performing a quantum error correction (QEC) on the modified qubit to obtain a QEC-corrected qubit.

13. The method according to claim 12, wherein:
the QEC comprises a concatenated QEC.

14. The method according to claim 12, wherein performing the QEC on the modified qubit to obtain the QEC-corrected qubit comprises:
correcting the modified qubit with a minimum weight prefect matching (MWPM) decoder to obtain the QEC-corrected qubit.

15-20. (canceled)

21. An apparatus for performing quantum computing, the apparatus comprising:
a first device configured to store a qubit and a second device configured to perform a gate operation on the qubit, wherein the apparatus is configured to perform:
obtaining and stabilizing the qubit;
determining a type of the NBP quantum gate associated with a quantum operation; and
applying, according to the type of the NBP quantum gate, the quantum operation on the qubit to obtain a modified qubit, the quantum operation comprising a base gate drive and a counterdiabatic (CD) control drive.

22. The apparatus according to claim 21, wherein:
the qubit comprises a Schrodinger Cat qubit comprising coherent quantum superposition of a plurality of quantum states.

23. The apparatus according to claim 21, wherein when the apparatus is configured to perform stabilizing the qubit, the apparatus is configured to perform:
stabilizing the qubit in a Kerr nonlinear oscillator with a parametric two-photon drive.

24. The apparatus according to claim 23, wherein the Kerr nonlinear oscillator with the parametric two-photon drive is associated with a stabilization Hamiltonian satisfying:
Ĥ_{KPO}=−K(â^{2†}−α²)(â²−α²),
wherein: Ĥ_{KPO} is the Hamiltonian for the Kerr oscillator, K indicates a strength of Kerr nonlinearity, α indicates a value in phase space, and â indicates an operator.

25. The apparatus according to claim 21, wherein:
the type of the NBP quantum gate comprises one of a Z rotation gate, a ZZ rotation gate, or a controlled-NOT (CX) gate.

26. The apparatus according to claim 21, wherein:
the CD control drive corresponds to a set of CD control pulses designed according to the type of the NBP quantum gate.

27. The apparatus according to claim 26, wherein:
the set of CD control pulses comprise a function of a set of truncated Gaussian pulses.

28. A non-transitory computer program product comprising a computer-readable program medium code stored thereupon, wherein the computer-readable program medium code, when executed by a processor, is configured to cause the processor to perform:
obtaining and stabilizing a qubit;
determining a type of the NBP quantum gate associated with a quantum operation; and
applying, according to the type of the NBP quantum gate, the quantum operation on the qubit to obtain a modified qubit, the quantum operation comprising a base gate drive and a counterdiabatic (CD) control drive.

29. The non-transitory computer program product according to claim 28, wherein:
the qubit comprises a Schrodinger Cat qubit comprising coherent quantum superposition of a plurality of quantum states.

30. The non-transitory computer program product according to claim 28, wherein:
when the computer-readable program medium code is configured to cause the processor to perform stabilizing the qubit, the computer-readable program medium code is configured to cause the processor to perform:
stabilizing the qubit in a Kerr nonlinear oscillator with a parametric two-photon drive; and
the Kerr nonlinear oscillator with the parametric two-photon drive is associated with a stabilization Hamiltonian satisfying:
Ĥ_{KPO}=−K(â^{2†}−α²)(â²−α²),
wherein: Ĥ_{KPO} is the Hamiltonian for the Kerr oscillator, K indicates a strength of Kerr nonlinearity, α indicates a value in phase space, and â indicates an operator.
